(19) United States
(12) Patent Application Publication
(10) Pub. No.: US 2023/0063504 A1
(43) Pub. Date: Mar. 2, 2023

(54) Energy Conversion Device, Apparatus and Related Methods

(71) Applicant: Birmingham Technologies, Inc., Arlington, VA (US)

(72) Inventor: Joseph Birmingham, Arlington, VA (US)

(73) Assignee: Birmingham Technologies, Inc., Arlington, VA (US)

(21) Appl. No.: 17/446,062

(22) Filed: Aug. 26, 2021

(51) Int. Cl. H02N 99/00

(52) U.S. Cl. CPC H02N 99/00

(57) ABSTRACT

An embodiment relates to an apparatus including first, second, and third electrodes and first and second transport media. The first electrode includes opposite first and second surfaces having first and second work function values, respectively. The second electrode includes a third surface facing the first surface and having a third work function value. The third electrode includes a fourth surface facing the second surface and having a fourth work function value. The third and fourth work function values are different than the first and second work function values. The third electrode is electrically coupled to the second electrode. The first transport medium is positioned between the first electrode and the second electrode and includes first nanoparticles. The second transport medium is positioned between the first electrode and the third electrode and includes second nanoparticles. In embodiments, the apparatus is coupled to an electrical load to power the load.

### BACKGROUND

Embodiments relate to electric power generation, conversion, and transfer. Certain embodiments relate to energy conversion devices, including nano-scale energy conversion devices that generate electric power through thermionic energy conversion and/or thermoelectric energy conversion.

Portable electric power generating devices are often used to power devices where access to electric power from the electric power grid is not practical (e.g., mobile phones and tablets in a shopping complex and satellites in orbit about the Earth). Such devices are also used when access to the grid is not possible (e.g., remote installations with intermittent or no grid availability). In addition, such devices are used as a backup power supply to support continued operation of critical equipment during a grid event (e.g., a blackout or a brownout).

Standard, portable electric power generation devices include gasoline engines and diesel engines. However, when in operation, these devices require frequent monitoring to ensure that necessary refueling is performed to maintain the devices in operation. Photoelectric devices, e.g., solar cells are effective only when sufficient light is available. Commercially available electric power storage devices include, for example, electrochemical batteries and solid state batteries. However, due to limited charges on electrochemical and solid state batteries, frequent replacement and/or recharging are required. In addition, electrochemical batteries and solid state batteries have a relatively large footprint when used for emergency and backup power supplies in industrial facilities. Similarly, microelectronic devices are not always compatible with the employment of electrochemical batteries and solid state batteries. One example of a microelectronic device possibly requiring a compact, long-life, low-current, electric power device is a low power electronic sensor which is installed for long-term unattended operation in an inaccessible location. Another example of a microelectronic device possibly requiring a compact, long-life, minimal power draw, is a nonvolatile memory circuit of a compact computing device.

Other portable power generation devices include fuel cells and nuclear batteries. Fuels cells require hydrogen replacement after a period of time and, similar to electrochemical and solid state batteries, fuel cells have a relatively large footprint when used as emergency and backup power supplies in industrial facilities. Nuclear batteries rely on processes that include fission, fusion, or radioactive decay of the nuclei of atoms. These processes are relatively inefficient and require shielding to reduce the emissions of ionizing radiation that are a natural by-product of the nuclear processes.

### SUMMARY

Aspects of the current subject matter include various embodiments of a compact energy conversion device. In one aspect, an energy conversion device is described that includes a transport medium comprising a nanoparticle suspended in a dielectric. The transport medium has a first side and a second side, with the first side opposing the second side. The nanoparticle comprises a conductive metal. The conductive metal is at least partially covered by a monolayer film. The monolayer film is less conductive than the conductive metal. The compact energy conversion device includes a first surface disposed at the first side of the transport medium with the first surface having a first work function. The energy conversion device also includes a second surface disposed at the second side of the transport medium with the second surface having a second work function. The first side work function is lower than the second work function. The energy conversion device is configured to power an application device coupled to the energy conversion device.

In some variations, one or more of the features disclosed herein including the following features can optionally be included in any feasible combination. In some implementations, a nanoparticle work function is lower than the second work function. In some variations, the dielectric is a solution comprising at least one of silicone oil, purified water, hexane, toluene, and tetradecane. In some variations, the monolayer film has a thickness less than ten nanometers, and wherein the conductive metal of the nanoparticle comprises at least one of gold, silver, platinum, titanium, platinum, lanthanum hexaboride, and copper. In some variations, the nanoparticle further comprises a core-shell nanoparticle, the core-shell nanoparticle including a conductive core and an insulative film. In some variations, the first surface comprises a surface feature including at least one of a spike, a sphere, a pin, and a pillar. In some variations, the first surface comprises at least one of Cs2O, CsF, CH3OH, CsCO3, chlorine compounds, fluorine compounds, cesium compounds, non-stoichiometric cesium oxides, and cesium fluorides. In some variations, the first surface comprises a semi-conductive material, the semi-conductive material being doped with at least one of aluminum, antimony, bismuth, gold, phosphorous and boron. In some variations, the first surface has covalent bonding in-plane and Van der Waals bonding out of plane, and wherein the first surface comprises at least one of WSe2, MoS2, MoTe2, and h-BN.

In another aspect, an energy conversion device is described that includes a first electrode having a first surface with the first surface having a first work function. The energy conversion device includes a second electrode having a second surface with the second surface having a second work function. The energy conversion device includes a transport medium interposed between the first surface and the second surface, the transport medium comprising traps suspended in a dielectric. The first work function is lower than the second work function. The energy conversion device is configured to power an application device coupled to the energy conversion device.

In some variations, one or more of the features disclosed herein including the following features can optionally be included in any feasible combination. In some implementations, the dielectric comprises a lattice of Ta2O5 and a tantalum dopant and the trap includes an opening in the lattice of Ta2O5 where no atom is bonded to the tantalum dopant. In some implementations, the first electrode and the second electrode have a surface treatment comprising at least one of Cs2O, CsF, CH3OH, CsCO3, chlorine compounds, fluorine compounds, cesium compounds, non-stoichiometric cesium oxides, and cesium fluorides. In some implementations, the dielectric is a polycrystalline layer having a crystalline structure, the traps are nanoparticles including a conductive metal, and wherein the first electrode comprises a semi-conductive material and the second electrode comprises at least one of Ti, Ni, Cu, Pd, Ag, Hf, ITO, W, Ir, Pt, Re, W, Mo and Au.

In yet another aspect, an energy conversion device is described including a first electrode having a first surface and a second surface in which the first surface and the second surface are associated with a first work function. The energy conversion device includes a second electrode facing the first surface with the second electrode associated with a second work function. The energy conversion device includes a third electrode facing the second surface with the third electrode associated with the second work function. The energy conversion device includes a first transport medium interposed between the first electrode and the second electrode. The energy conversion device includes a second transport medium interposed between the first electrode and the third electrode. The second electrode and the third electrode are electrically coupled and the first work function is lower than the second work function. The energy conversion device is configured to power an application device coupled to the energy conversion device.

In some variations, one or more of the features disclosed herein including the following features can optionally be included in any feasible combination. In some implementations, the first electrode and the second electrode are on opposing sides of the first transport medium, and wherein the second electrode and the third electrode are on opposing sides of the second transport medium. In some implementations, the first surface contacts the first transport medium and the second surface contacts the second transport medium. In some implementations, the energy conversion device further includes a first lead, the first lead oriented in a first direction non-parallel to the first surface and the second surface, the first lead electrically connected to the second electrode and the third electrode; and a second lead, the second lead oriented in a second direction non-perpendicular to the first lead, the second lead electrically coupled to the first electrode. In some implementations, the first direction is the same as the second direction, and wherein the first lead extends at least a distance between the second electrode and the third electrode. In some implementations, the second lead faces an exposed region of the first electrode, and wherein the first lead is on an opposing side of the exposed region of the first electrode.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to an energy conversion device, it should be readily understood that such features are not intended to be limiting. The claims that follow this disclosure are intended to define the scope of the protected subject matter.

Other aspects disclosed herein include systems, devices, components, apparatuses, assemblies, circuits, methods, and processes. Features of these and other aspects will become apparent from the following detailed description of exemplary embodiments, taken in conjunction with the accompanying drawings.

### BRIEF DESCRIPTION OF THE SEVERAL VIEWS OF THE DRAWINGS

The accompanying drawings are intended to be illustrative and may not necessarily be to scale in absolute terms or comparatively. Also, the relative placement of features and elements may be modified for the purpose of illustrative clarity. The accompanying drawings, which are incorporated in and constitute a part of this specification, show certain aspects of the subject matter disclosed herein and, together with the description, help explain some of the principles associated with the disclosed implementations. In the drawings,

FIG. 1 depicts a cutaway view of one embodiment of an energy conversion device;

FIGS. 2A and 2B collectively depict a flow chart illustrating a process for manufacturing an energy conversion device;

FIG. 3 depicts a cutaway view of an embodiment of a partially constructed energy conversion device;

FIG. 4 depicts a table of elemental work function values of bulk materials;

FIG. 5 depicts a perspective view of a process for depositing a thermionic electron emissive material on an electrode substrate;

FIG. 6 depicts a graphical representation of work function values as a function of particle size;

FIG. 7 depicts a plan view of a covalently-bonded dipole deposited on the surface of an electrode through an electrospray deposition of a thermionic electron emissive material on the electrode substrate;

FIG. 8 depicts a cutaway view of an embodiment of a nanofluid including a plurality of nanoparticle clusters suspended in a dielectric medium;

FIG. 9 depicts a flow chart illustrating a process for generating electric power with an energy conversion device according to an exemplary embodiment;

FIG. 10 depicts a cutaway view of an embodiment of an energy conversion device showing a relationship between the work functions of the electrodes and nanofluid therein;

FIG. 11 depicts a graphical representation of the effect of the emitter work function value being larger than the collector work function value according to an embodiment;

FIG. 12 depicts a schematic view of a plurality of nanoscale particles depicting electron transfer;

FIG. 13 is a block diagram illustrating an embodiment of an energy conversion device;

FIG. 14 depicts a schematic view of a system of stacked or grouped energy conversion devices that generates electric power from waste heat;

FIG. 15 depicts a cutaway view of waste heat harvesting system that includes an energy conversion device coupled to an electronic chip that harvests electrical energy from waste heat from the electronic chip;

FIG. 16 depicts an exploded view of an electric power generation system that includes an array of energy conversion devices coupled to an array of solar cells that harvests electrical energy from waste heat from the solar cell array;

FIG. 17A shows a schematic representation of an architecture for an energy conversion device, in accordance with some example embodiments;

FIG. 17B shows an energy-generating layer including a surface treatment, in accordance with some example embodiments;

FIG. 17C shows another energy-generating layer including a low work function surface and a high work function surface, in accordance with some example embodiments;

FIG. 18A shows another energy-generating layer including a nanoparticle solution, in accordance with some example embodiments;

FIG. 18B shows a schematic representation of an architecture of an energy conversion device including the nanoparticle solution, in accordance with some example embodiments;

FIG. 19A shows nanoparticles in accordance with some example embodiments;

FIG. 19B shows nanoparticles in a transport medium interposed between the emitter and the collector in accordance with some example embodiments;

FIG. 20 shows an atomic layer including a trap for trap-assisted charge carrier transport, in accordance with some example embodiments;

FIG. 21 shows a polyatomic layer including a trap for trap-assisted charge carrier transport, in accordance with some example embodiments;

FIG. 22 shows a bandgap diagram depicting applied charge carrier tunneling techniques and Poole-Frenkel Emission in accordance with some example embodiments;

FIG. 23 shows another bandgap diagram depicting applied charge carrier tunneling techniques and Poole-Frenkel Emission in accordance with some example embodiments;

FIG. 24A shows an exploded view of standoff pillars resulting from an etch, in accordance with some example embodiments;

FIG. 24B shows a cross-sectional view of standoff pillars resulting from an etch, in accordance with some example embodiments;

FIG. 24C shows a side view of standoff pillars resulting from an etch, in accordance with some example embodiments;

FIG. 24D shows a top view of standoff pillars resulting from an etch, in accordance with some example embodiments;

FIG. 25A shows an exploded view of standoff columns resulting from an etch, in accordance with some example embodiments;

FIG. 25B shows a cross-sectional view of standoff columns resulting from an etch, in accordance with some example embodiments;

FIG. 25C shows a side view of standoff columns resulting from an etch, in accordance with some example embodiments;

FIG. 25D shows a top view of standoff columns resulting from an etch, in accordance with some example embodiments;

FIG. 26 shows a block diagram of the energy conversion device coupled to an application device;

FIG. 27 shows a block diagram of an energy conversion system for an application device;

FIG. 28 shows another block diagram of an energy conversion system including an output controller coupled to an application; and

FIG. 29 shows another block diagram of an energy conversion system including an environmental enhancement.

### DETAILED DESCRIPTION

It will be readily understood that the components and features of the exemplary embodiments, as generally described herein and illustrated in the Figures, may be arranged and designed in a wide variety of different configurations. Thus, the following detailed description of the embodiments of the methods, devices, assemblies, apparatus, systems, compositions, etc. of the exemplary embodiments, as presented in the Figures, is not intended to limit the scope of the embodiments, as claimed, but is merely representative of selected embodiments.

Reference throughout this specification to “a select embodiment,” “one embodiment,” “an exemplary embodiment,” “exemplary embodiments,” “an embodiment,” or “embodiments” means that a particular feature, structure, or characteristic described in connection with the embodiment(s) is included in at least one embodiment. Thus, appearances of the phrases “in a select embodiment,” “in one embodiment,” “in an exemplary embodiment,” “in exemplary embodiments,” “in an embodiment,” or “in embodiments” in various places throughout this specification are not necessarily referring to the same embodiment(s) or only a single embodiment. The embodiments may be combined with one another in various combinations and modified to include features of one another.

The illustrated embodiments will be best understood by reference to the drawings, wherein like parts are designated by like numerals throughout. The following description is intended only by way of example, and illustrates certain selected embodiments of methods, devices, assemblies, apparatus, systems, etc. When practical, similar reference numbers denote similar structures, features, or elements.

Thermoelectric power conversion presents a way to harvest available waste heat and convert this thermal energy into electricity. In an embodiment, thermoelectric power generation involves the attachment of one electrode to a different electrode to form a junction therebetween, where the two electrodes experience a temperature gradient. Based on the Seebeck effect, the temperature gradient induces a voltage. Higher temperature differentials tend to produce higher voltages and electric currents. However, due to the transfer of heat between the two materials at the junction, a thermal backflow is introduced which reduces the efficiency of thermoelectric power conversion systems. Some nuclear batteries (as described above) include the combination of technologies such as photovoltaic batteries and thermoelectric batteries. In the photovoltaic battery, nuclear radiation energy is first converted into electromagnetic radiation, typically by irradiating a phosphorescent material and then exposing a semiconductor p-n junction to electromagnetic radiation to produce low voltage electrical current in. In the thermoelectric battery, the nuclear radiation is converted into thermal energy that in turn is converted to electrical energy by thermoelectric conversion.

Thermionic power conversion also provides a method to convert heat into electrical energy. Thermoelectric power conversion generators convert heat energy to electrical energy by an emission of electrons from an emitter electrode (i.e., a cathode), which may be subjected to heat. Electrons flow from the emitter electrode, across an inter-electrode gap, to a collector electrode (i.e., an anode), through an electrically conductive path to an electrical load, and return back to the emitter electrode, thereby converting heat to electrical energy for use to power the load.

Recent improvements in thermionic power converters pertain to material selection based on work functions and corresponding work function values for the electrodes and using a fluid to fill the inter-electrode gap. Electron transfer density is limited by the materials of the electrodes and the materials of the fluid in the inter-electrode gap (e.g., the associated work functions). Representative and exemplary materials, features, conditions, etc. associated with thermionic devices are described in further detail below.

Construction of the (Nano-Scale) Energy Conversion Device

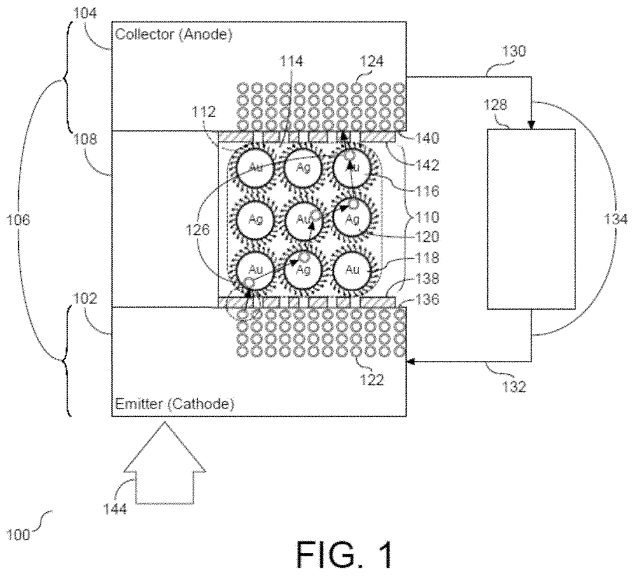

To provide additional details for an improved understanding of selected embodiments of the present disclosure, reference is now made to FIG. 1 illustrating a cutaway view of an embodiment of an energy conversion device (100) that is configured to generate electrical power. In exemplary embodiments, the energy conversion device (100) may be nano-scale and/or contain one or more nano-scale components. The energy conversion device (100) is sometimes referred to as a cell or a layer of an apparatus. For example, a plurality of devices (100) may be organized as a plurality of cells or a plurality of layers electrically connected to one another in series or parallel, or a combination of both series and parallel to generate electrical power at the desired voltage, current, and power output. The energy conversion device (100) includes an emitter electrode (also referred to as a cathode) (102) and a collector electrode (also referred to as an anode) (104). The emitter electrode (102) and collector electrode (104) are collectively referred to as the electrodes (106) of the energy conversion device (100), which as mentioned above is a nano-scale energy device in certain exemplary embodiments. One or more insulator posts, sometimes referred to as columns, standoffs, or micro-pillars, one of which is shown in FIG. 1 and designated by reference numeral (108), maintain separation between the emitter electrode (102) and the collector electrode (104) such that the electrodes (106) and the one or more insulator posts (108) define one or more cavities, one of which is shown in FIG. 1 and designated by reference numeral (110). In an embodiment, the one or more insulator posts (108) are fabricated with a dielectric material, such as, and without limitation, alkanethiol, an aerogel made from a sol-gel, corona dope, super corona dope, silicon, silicon-oxide, polymer, or any dielectric material. In an embodiment, rather than insulator posts (108), one or more insulator walls (not shown) are formed that divide the cavity (110). The cavity (110) extends between the electrodes (106) for a distance in the range from about 1 nanometer (nm) to less than about 10 nm. A nanofluid (112) is maintained within the cavity (110). Accordingly, in an embodiment the energy conversion device or cell (100) includes two spaced electrodes (102) and (104) separated by the insulator post(s) (108) with the cavity (110) filled with a nanofluid (112) between the electrodes (102) and (104).

In an embodiment, the emitter electrode (102) and the collector electrode (104) are fabricated with different materials from one another. In an embodiment, those materials have different work function values from one another. The work function of a material or a combination of materials is the minimum thermodynamic work, i.e., minimum energy, needed to remove an electron from a solid to a point in a vacuum immediately outside a solid surface of the material. The work function is a material-dependent characteristic. Work function values are typically expressed in units of electron volts (eV). Accordingly, the work function of a material determines the minimum energy required for electrons to escape the surface, with lower work functions generally facilitating electron emission.

According to an embodiment, the emitter electrode (102) has a higher work function value than the collector electrode (104). According to another embodiment, the collector electrode (104) has a higher work function value than the emitter electrode (102). The difference in work function values between the electrodes (106) is, in exemplary embodiments, due to the different electrode materials, which induces a contact potential difference between the electrodes (106). In an embodiment, the contact potential difference is overcome to transmit electrons through the nanofluid (112) within the cavity (110) from the emitter electrode (102) to the collector electrode (104). Both electrodes (106) emit electrons. However, as explained in more detail elsewhere herein, once the contact potential difference is overcome, in an embodiment the emitter electrode (102) emits significantly more electrons than the collector electrode (104). A net flow of electrons is transferred from the emitter electrode (102) to the collector electrode (104), and a net electron current will flow from the emitter electrode (102) to the collector electrode (104). This net electron current causes the emitter electrode (102) to become positively charged and the collector electrode (104) to become negatively charged. Accordingly, the energy conversion device (100) generates an electron current that is transmitted from the emitter electrode (102) to the collector electrode (104).

In an exemplary embodiment, the nanofluid (112) includes a dielectric medium (114) and a plurality of nanoparticle clusters (116) suspended in the dielectric medium (114). In an embodiment, the nanofluid (112) reduces or minimizes ohmic heating and reduces or eliminates formation of space charges in the cavity (110) such that arcing in the medium (114) is reduced or prevented. In some embodiments, and without limitation, the dielectric medium (114) is water, silicone oil, alcohol, or a combination comprising any combination thereof. Also, in at least one embodiment, the dielectric medium (114) is an aerogel with relatively low thermal conductivity that reduces heat transfer therethrough. For example, the thermal conductivity values may be less than 1.0 watts per meter-degrees Kelvin (W/m·K). In at least one embodiment, the thermal conductivity of the dielectric medium (114) is as low as 0.013 watts per meter-degrees Kelvin (W/m·K), as compared to the thermal conductivity of water at 20 degrees Celsius (° C.) of 0.6 W/m·K. Accordingly, in an embodiment, the nanofluid (112) reduces or minimizes heat transfer through the cavity (110) with low thermal conductivity values. In an embodiment, the heat transport in the nanofluid (112) is proportional to the temperature difference between the electrodes (102) and (104). For example, if the heat transport in a low thermal conductivity nanofluid is small, a high temperature difference between the two electrodes (102) and (104) can be maintained during operation. As discussed elsewhere herein, the electrical conductivity of the nanofluid (112) may change with operation of the corresponding device.

The nanoparticle clusters (116) may be fabricated from metal and metal alloys, ceramics, cermet, composites, other materials, or combinations thereof. Some of the nanoparticle clusters (116) may include materials dissimilar from other nanoparticle clusters (116). In an embodiment, and without limitation, the nanofluid (112) includes nanoparticle clusters (116) of gold (Au) (118) and silver (Ag) (120). As used herein, “nanoparticle clusters” refers to a grouping of 6 to 8 atoms of the associated materials, e.g., Au and Ag, where the number of atoms is non-limiting. In an embodiment, the nanoparticle clusters (116) have work function values that are greater than the work function values for the electrodes (106). The work function values of the Au nanoparticle clusters (118) and the Ag nanoparticle clusters (120) are 4.1 eV and 3.8 eV, respectively. As explained in more detail elsewhere herein, in an embodiment charge transport through electron hopping and Brownian motion is facilitated by the greater work function values of the nanoparticle clusters (116) and use of at least two types of nanoparticle clusters (116), each type with a different work function value. The Brownian motion of the nanoparticle clusters (116) includes collisions between the nanoparticle clusters (116) among themselves and collisions between the nanoparticle clusters (116) and the electrodes (102) and (104).

According to an embodiment, the nanoparticle clusters (116) are coated with, for example, an alkanethiol to form a dielectric barrier thereon, where the selection of alkanethiol is non-limiting. In at least one embodiment, dodecanethiol, decanetil, or a combination thereof is used. In at least one embodiment, at least one other alkane shorter than dodecanethiol and decanethiol is used. In an embodiment, the length of the alkane chain is less than 1 nm. This embodiment facilitates the transfer of electrons from one nanoparticle cluster (116) to another. In an embodiment, the alkanethiol coating reduces coalescence of the nanoparticle clusters (116). In an embodiment, the nanoparticle clusters (116) have a diameter in the range of 0.5 nm to 5 nm. In at least one embodiment, the nanoparticle clusters (116) have a diameter in the range of 1-3 nm. In an embodiment, the nanoparticle clusters (116) have a diameter of 2 nm. The nanoparticle clusters (116) of Au (118) and Ag (120) are tailored to be electrically conductive with charge storage features. It should be understood, however, that materials other than gold and silver (or in addition to gold and/or silver) may be used. Accordingly, the nanofluid (112), including the suspended nanoparticle clusters (116), provides a conductive pathway for electrons to travel across the cavity (110) from the emitter electrode (102) to the collector electrode (104) through charge transfer.

A first plurality of electrons (122) and a second plurality of electrons (124) are shown proximal to the cavity (110) within the emitter electrode (102) and the collector electrode (104), respectively. An electron (126) is shown, per an embodiment, leaving the emitter electrode (102), hopping across the nanoparticle clusters (116), and entering the collector electrode (104).

FIG. 1 illustrates an external circuit (e.g., an electrical load) (128) connected to the two electrodes (106). Specifically, a first electrical conductor (130) connects the collector electrode (104) and the external circuit (e.g., electrical load) (128), and a second electrical conductor (132) connects to the external circuit (e.g., electrical load) (128) and the emitter electrode (102). In embodiments, when the (nano-scale) energy conversion device (100) is in service generating electricity, an external circuit electron current (134) is transmitted through external circuit or electrical load (128), and the same amount of electron current as flowing through the external circuit (134) will flow from the emitter electrode (102) to the collector electrode (104). For example, a single cell or layer, such as the configuration shown and described in FIG. 1, can generate a voltage within a range extending between about 0.25 volts and 6.0 volts, depending on the contact potential difference (discussed further herein) induced between the emitter electrode (102) and the collector electrode (104) as a function of the materials used for each.

In some embodiments, the device (100) nominally generates, by way of example, between about 0.75 volts and 5.0 volts. In an embodiment, the device (100) generates about 0.75 volts. Also, for example, a single cell or layer, such as the configuration shown and described in FIG. 1, the device (100) can generate an electrical current within a range of approximately 1 milliampere (ma) to approximately 10 ma in an example. Further, in some embodiments, the device (100) generates approximately 0.75 milliwatts per square centimeter (mW/cm²). Accordingly, in exemplary embodiments the energy conversion device (100), even at a nano-scale, generates sufficient electrical current to power small loads, e.g., a micro-circuit.

According to an embodiment, the emitter electrode (102) has a tungsten (W) surface, and in an exemplary embodiment a nanoparticle surface (136) and a cesium oxide (Cs₂O) coating (138) that at least partially covers the tungsten (W) nanoparticle surface (136). In an embodiment, the collector electrode (104) has a gold (Au) surface, an in an exemplary embodiment a gold (Au) nanoparticle surface (140) and a Cs₂O coating (142) that at least partially covers the Au nanoparticle surface (140). As discussed further herein, according to an embodiment during manufacturing of the electrodes (106), W nanoparticles are electrosprayed onto one side of polymer base that includes, according to an embodiment, a graphene film, e.g., an atomic-scale lattice of carbon atoms, on one side of the polymer base. The W nanoparticles form a surface layer on the graphene film. According to an embodiment, the Cs₂O coating (138) on the W nanoparticle surface (136) is deposited on the surface (136) through a template. The polymer base may act as a sacrificial component, with the polymer base being removed with, for example, acetone (described further herein). Similarly, according to an embodiment the Au nanoparticles are electrosprayed onto a graphene film on a polymer base to form the Au nanoparticle surface (140), and the Cs₂O coating (142) is deposited on the Au nanoparticle surface (140), for example, through a template, and the polymer base is removed. The use of the templates with particular electrospray and nanofabrication techniques form deposited layers of Cs₂O (138) and (142) in one or more predetermined patterns on the W nanoparticle surface (136) and the Au nanoparticle surface (140). A percentage of coverage of each of the two substrates (136) and (140) with the respective Cs₂O coating layers (138) and (142) is, according to an embodiment, within a range of at least 50% up to 70%, and in at least one embodiment, is about 60%. The Cs₂O coatings (138) and (142) reduce the work function values of the electrodes (102) and (104) from the work function values of W (typically 4.55 eV) and Au (typically 5.1 eV), respectively. According to an embodiment, the emitter electrode (102) (including the tungsten and cesium oxide) has a work function value of 0.88 electron volts (eV) and the collector electrode (104) (including the gold and cesium oxide) has a work function value of 0.65 eV. Accordingly, lower work function values of the electrodes (102) and (104), such as those described above, are desirable to the operation of the energy conversion device (100) as described herein.

W and Au are selected for the electrodes (106) in an embodiment due to, at least, their metallic properties (e.g., strength and resistance to corrosion) and the measured change in work function when the thermionic emissive material such as Cs₂O is layered thereon. Alternative materials that may be used for the electrodes (106) include, noble metals including, and without limitation, rhenium (Re), osmium (Os), ruthenium (Ru), iridium (Jr), rhodium (Rh), palladium (Pd), and platinum (Pt), or any combination of these metals. In addition, and without limitation, non-noble metals such as tantalum (Ta), aluminum (Al) and molybdenum (Mo) may also be used. For example, and without limitation, Al nanoparticles may be used rather than W nanoparticles to form the surface (136), and Pt nanoparticles may be used rather than Au nanoparticles to form the surface (140). Accordingly, the selection of the materials to use to form the nanoparticle surfaces (136) and (140) is principally based on the work functions of the electrodes (106), and more specifically, the difference in the work functions once the electrodes (106) are fully fabricated.

In exemplary embodiments, the energy conversion device (100) generates electric power through harvesting heat energy (144). As described in further detail herein, the emitter electrode (102) receives the heat energy (144) from sources that include, without limitation, heat generating sources and ambient environments, and emits electrons (126) that traverse the cavity (110) via the nanoparticle clusters (116). The electrons (126) reach the collector electrode (104), and external circuit current (134) is transmitted to the external circuit (124). In some embodiments, the (nano-scale) energy conversion device (100) generates electrical power through placement in ambient, room temperature environments. Accordingly, in exemplary embodiments, the energy conversion device (100) harvests heat energy (144), including waste heat, to generate useful electrical power.

Assembly of the (Nano-scale) Energy Conversion Device

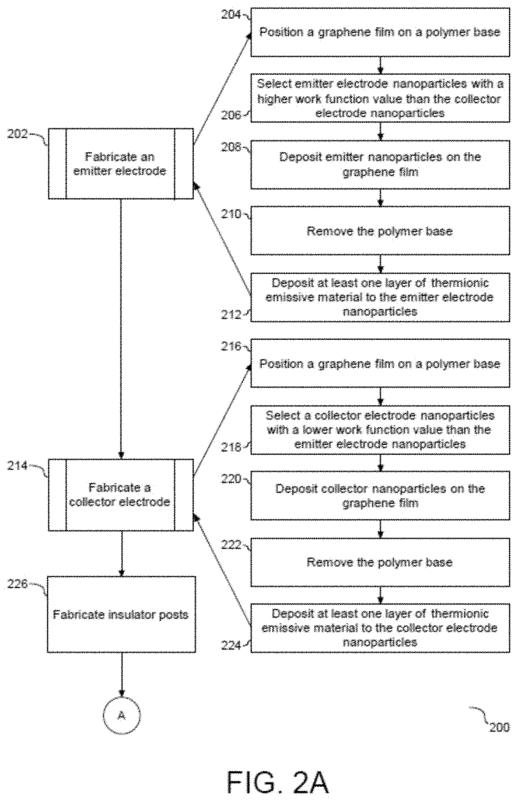

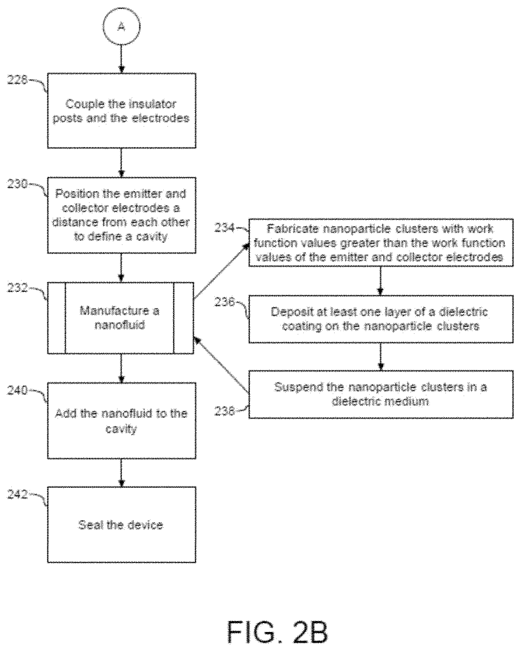

Referring to FIGS. 2A and 2B, a flow chart (200) is provided illustrating a process for manufacturing a (nano-scale) energy conversion device. Referring to FIG. 3, a diagram (300) is provided illustrating a cutaway view of one embodiment of a partially constructed energy conversion device (300), which may be nano-scale (and is not shown to scale).

Fabrication of the Emitter Electrode (Cathode)

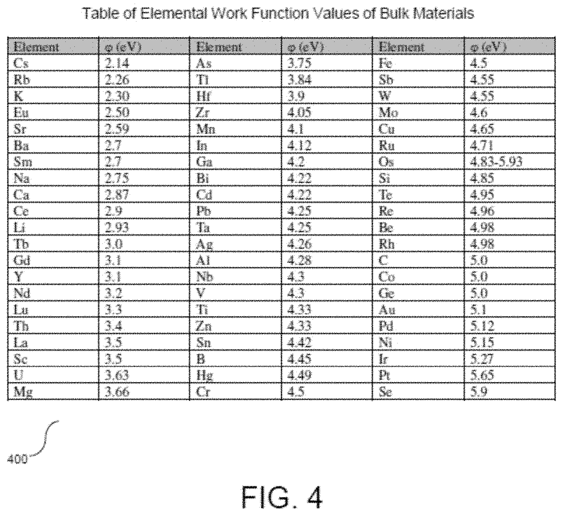

As shown and described in FIGS. 2A, 2B, and 3, in an embodiment an emitter electrode (302) is fabricated (202) by positioning (204) a graphene film (328) on one side of a polymer base (330) (shown in phantom). The polymer base (330) is approximately 2 nm thick (where this value should be considered non-limiting) and the graphene film (328) is approximately 3.7 angstroms thick (where this value also should be considered non-limiting). The polymer base (330) is used as a sacrificial assembly component. The graphene film (328) is positioned proximate to an electrospray nozzle of an electrospray device (see FIG. 5, electrospray nozzle (512)). Emitter electrode nanoparticles (not shown) are selected (206) for deposition (208) on the graphene film (328).

In an embodiment, a characteristic of selection (206) of the nanoparticle material(s) for the emitter electrode (302) is that the combination of the nanoparticle material and the deposited thermionic emissive material have a combined work function value greater than the work function value of the collector electrode (306) (fabricated as described further elsewhere herein). In another embodiment, a characteristic of selection (206) of the nanoparticle material(s) for the emitter electrode (302) is that the combination of the nanoparticle material and the deposited thermionic emissive material have a combined work function value less than the work function value of the collector electrode (306) (fabricated as described further elsewhere herein).

Another embodiment has a characteristic that the difference of the work function values of the two electrodes (302) and (306) (as measured in eV) is above a predetermined value to increase, and preferably maximize, electron transfer between the two electrodes (302) and (306). A partial list of the appropriate nanoparticle materials for the emitter electrode (302) is provided elsewhere herein. In the exemplary embodiment, at least one layer of W nanoparticles (not shown) is deposited (208) through electrospray onto the graphene film (328) to form a nanoparticle surface (304) on the graphene film (328). In at least one embodiment, the thickness of the layer of nanoparticles to form nanoparticle surface (304) is approximately 2 nm (i.e., the approximate thickness of a nanoparticle), where the 2 nm value should be considered non-limiting. Accordingly, in an embodiment, one or more metal materials in the form of nanoparticles are selected as the nanoparticle surface (304) for the emitter electrodes (302) at least partially as a function of decreasing the work function value of the electrodes (302) and (306) and maintaining a work function value differential between the electrodes (302) and (306) above a predetermined value.

Once the W nanoparticle surface (304) is formed (208), the polymer base (330) is removed (210) through, for example, an acetone solution, thereby rendering the polymer base (330) as a sacrificial material. Accordingly, in an embodiment the W nanoparticle surface (304) on the graphene film (328) is ready to receive a thermionic emissive material thereon.

In an embodiment, at least one layer of a thermionic electron emissive material (308) is deposited (212) on at least a portion of the W nanoparticle surface (304). In an embodiment, a monolayer of the thermionic electron emissive material (308) is deposited (212) on the surface (304). The thermionic electron emissive material (308), which may be in the form of a monolayer, may be deposited over, for example, about at least 50% to about 70% of the surface of the W nanoparticle surface (304). In another embodiment, about 60% of the surface of the W nanoparticle surface (304) receives the thermionic electron emissive material (308), which may be deposited as a monolayer. In yet another embodiment, a plurality of layers of the thermionic electron emissive material (308) is deposited on about 60% of the W nanoparticle surface (304). In an embodiment, the deposited thermionic electron emissive material (308) is selected to decrease the work function value of the emitter electrode (302) to a value below that of the work function value of the material selected for the W nanoparticle surface (304).

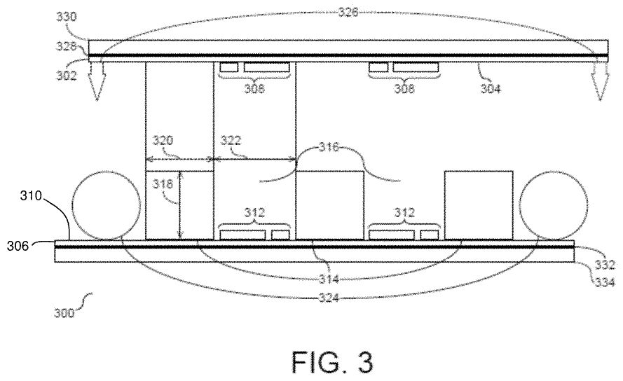

Referring to FIG. 4, a table (400) is provided illustrating elemental work function values of bulk materials. For example, the work function value of W is 4.55 eV. As described further herein, the deposition of Cs₂O (308) on the W nanoparticle surface (304) decreases the work function value of emitter electrode (302) to about 0.88 eV. Accordingly, combinations of materials are positioned to create the desired work function values, and modifying the combinations of materials can change the work function values of the combination.

The selection of the thermionic electron emissive material (308) to deposit on the nanoparticle surface (304) is, in accordance with an embodiment, partially based on the desired work function value of the electrode (302) (and electrode (306)) and chemical compatibility between the nanoparticle surface (304) and the deposited material (308). Deposition materials include, but are not limited to, thorium, aluminum, cerium, and scandium, as well as oxides of alkali or alkaline earth metals, such as cesium, barium, calcium, and strontium.

Referring to FIG. 5, a diagram is provided illustrating a perspective view of a process (500) for depositing a thermionic electron emissive material on an electrode substrate, e.g., a nanoparticle surface such as W nanoparticle surface (136/304) and Au nanoparticle surface (140/310). In a first step (502), a template (504) is positioned proximate to a substrate (506). The template (504) includes a pattern (508) of openings corresponding to a desired deposition pattern on the substrate (506). The template (504) is positioned over one side of the substrate (506) as shown by the arrow (524). The substrate (506) is grounded to facilitate direct deposition of droplets on the substrate (506) to form a pattern of the deposited deposition material(s).

In a second step (510), the substrate (506) with the overlaid template (504) is positioned proximate to an electrospray nozzle (512) of an electrospray device (not shown). An emission of the thermionic electron emissive material issues from the electrospray nozzle (512) as monodispersed droplets (514) is characterized by nanoparticles of uniform size in a dispersed phase. An electrospray of the droplets (514), hereinafter referred to as electrospray, produces monodisperse particles to support deposition of the thermionic electron emissive material in the nanometric scale range. In one embodiment, the electrospray (514) includes a solution of 0.1 molar (M) Cs₂O nanoparticles in ethanol, where the droplet diameter is 10 microns. Also, in one embodiment, the pattern (508) includes a range of 30-50 micron diameter holes with a center-to-center distance ranging from about 60-200 microns, staggered at about 30-60 degree angles, and preferably 45 degree angles. The electrospray (514) with Cs₂O nanoparticles is directed toward the template (504) to form a monolayer (516) as the template (504) and substrate (506) traverse the electrospray (514) as shown by the arrow (526). In an embodiment, 10¹⁴ Cs₂O atoms per square centimeter (cm²) is the target concentration for the substrate (506).

In a third step (518), the template (504) is separated from the substrate (506) as shown by the arrow (528) to leave a patterned thermionic electron emissive material (520) on electrode substrate (506) to form an emitter electrode (522). As shown, four distinct lines of deposited material, collectively referred to as deposited material (520), are overlaid on the W substrate (506). This pattern is merely an example pattern and should not be considered limiting. In an embodiment, the pattern of thermionic electrons may vary as long as the pattern enables operation of the electrode (522). Accordingly, a monolayer of patterned thermionic electron emissive material (520), e.g., Cs₂O, is formed on a W substrate (506) to achieve coverage of the substrate (506) in excess of at least 50% to about 70%, with 60% being an optimal coverage. In at least one embodiment, the thickness of the layer of patterned thermionic electron emissive material (520) is approximately 2 nm, where the 2 nm value should be considered non-limiting.

Exemplary electrospray and nano-fabrication technique(s) and associated equipment, including three-dimensional printing and four-dimensional printing (in which the fourth dimension is varying the nanoscale composition during printing to tailor properties) for forming the devices disclosed herein, including in accordance with the embodiment of FIG. 5, including the electrospray nozzle (512), are set forth in U.S. Application Publication No. 2015/0251213 published Sep. 10, 2015 entitled “Electrospray Pinning of NanoGrained Depositions,” U.S. Application Publication No. 2020/0369516 published Nov. 26, 2020 (corresponding to Ser. No. 16/416,849 filed May 20, 2019) entitled “Single-Nozzle Apparatus for Engineered Nano-Scale Electrospray Depositions,” U.S. Application Publication No. 2020/0368848 published Nov. 26, 2020 (corresponding to Ser. No. 16/416,858 filed May 20, 2019) entitled “Multi-Nozzle Apparatus for Engineered Nano-Scale Electrospray Depositions,” and in U.S. Application Publication No. 2020/0370158 published Nov. 26, 2020 (corresponding to Ser. No. 16/416,869 filed May 20, 2019) entitled “Method of Fabricating Nano-Structures with Engineered Nano-Scale Electrospray Depositions.” The apparatus and methods of those applications may be practiced alone or in combination with one another for making the various layers and components of the thermionic devices disclosed herein. Generally, those applications include disclosures of embodiments regarding, among other things, a composition including a nano-structural material, grain growth inhibitor nanoparticles, and/or at least one of a tailoring solute or tailoring nanoparticles. Any one of more of those compositional components (e.g., grain growth inhibitors) may be excluded from the embodiments described herein.

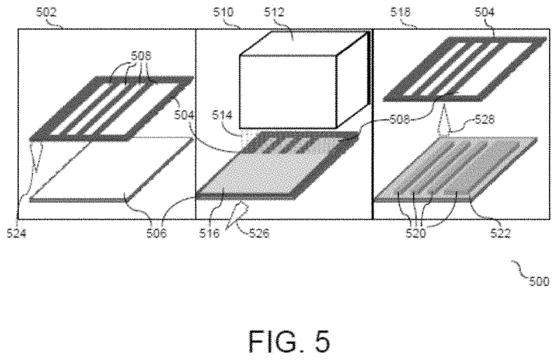

Referring to FIG. 6, a diagram is provided illustrating a graphical representation (600) of work function values as a function of particle size. The graph (600) includes a first axis (602), represented herein as a vertical axis (602) that indicates a change in work function value (Δϕ), where the vertical axis has a range from 0 to 1.2 in increments of 0.2 and in units of eV. The graph (600) also includes a second axis (604), represented herein as a horizontal axis that indicates particle size, where the second axis (604) extends from 0 to 60 in increments of 10 and in units of nanometers (nm). The graph (600) also includes a curve (606) representing the relationship between the particle size and the change in work function value associated with the size. As indicated in the graph (600), the selection of nanoparticle size impacts its work function value. For example, the work function value changes more than 1 eV as the nanoparticle cluster approaches that of a single atom. Conversely, as the nanoparticle size enlarges, the work function value approaches measurements associated with bulk materials. This property of a work function value of a material increasing with decreasing particle size enables the tailoring of each individual application of the energy conversion device (100). Accordingly, selecting the particular nanoparticle sizes for the spray depositions (520) on the emitter and collector electrodes (102)/(302) and (104)/(306), respectively, is performed to increase the work function difference between the electrodes to increase the number of electrons transferred during operation of the (nano-scale) energy conversion device (100).

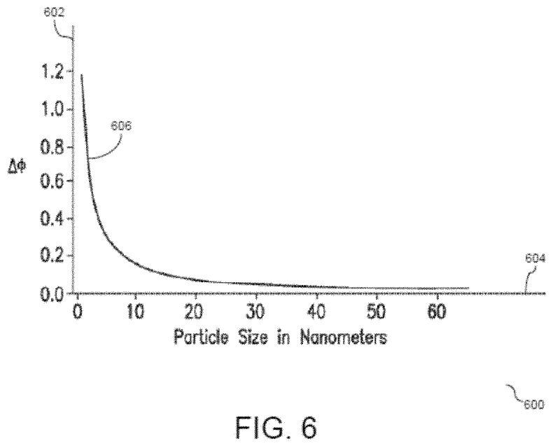

Referring to FIG. 7, a diagram is provided illustrating an overhead view (700) of a covalently-bonded dipole (702) deposited on the nanoparticle surface (136/304/506/704) of an electrode (302/306) through an electrospray (514) deposition of the thermionic electron emissive material on the electrode nanoparticle surface/substrate (136/304)/(506/704), in accordance with an embodiment. In an embodiment, the nanoparticles in the Cs₂O deposited on the electrode nanoparticle surface (704) form covalent bonds that in turn form the surface dipoles (702) (only one shown in FIG. 7). Within the dipoles (702), a positive charge (706) and an opposing negative charge (708) are formed by charged nano-droplets in the electrospray (514) as they collide with the surface (704). The charges (706) and (708) induce an electric field (710) between the charges (706) and (708) such that the dipole (702) acts as a nano-antenna that modifies the proximate dipole moment in the vicinity of the dipole (702) through inducement of electromagnetic waves proximate thereto as a function of the induced electric field (710). Accordingly, covalently-bonded dipoles (702) deposited on an electrode nanoparticle surface (704) create a low work function electrode, especially when the coverage area is optimized.

In at least one embodiment, the W emitter electrode (302) and the Au collector electrode (306) have dimensions of 20-50 millimeters (mm) long by 20-50 mm wide and 4-100 nm thick. The 100 nm thickness is based on charge penetration from the emitter electrode (102/302) into the nanofluid (112) and from the collector electrode (104/306) into the second electrical conductor (132). In general, to maximize the charge penetration through the associated electrodes (102/302 and 104/306), a smaller value of the associated thickness is preferred. Therefore, in at least one embodiment, electrodes (102/302 and 104/306) are approximately 4 nm thick.

Fabrication of the Collector Electrode (Anode)

Referring again to FIGS. 2A, 2B, and 3, in an embodiment the collector electrode (306) is fabricated (214) in a manner substantially similar to that for the emitter electrode (302). A graphene film (332) is positioned (216) on one side of a polymer base (334) (shown in phantom). The polymer base (334) is approximately 2 nm thick (where this value should be considered non-limiting) and the graphene film (332) is approximately 3.7 angstroms thick. The graphene film (332) is positioned proximate to an electrospray nozzle of an electrospray device (see FIG. 5, electrospray nozzle (512)). Collector electrode nanoparticles (not shown) are selected (218) for deposition (220) on the graphene film (332). In an embodiment, a characteristic for selection (218) of the nanoparticle material(s) for the collector electrode (306) is that the combination of the nanoparticle material and the deposited thermionic emissive material have a combined work function value less than the work function value of the emitter electrode (302) (fabricated as described elsewhere herein). In an alternative embodiment, a characteristic for selection (218) of the nanoparticle material(s) for the collector electrode (306) is that the combination of the nanoparticle material and the deposited thermionic emissive material have a combined work function value greater than the work function value of the emitter electrode (302) (fabricated as described elsewhere herein). A second characteristic of an embodiment is that the difference of the work function values of the two electrodes (302) and (306) (as measured in eV) be above a predetermined value to maximize electron transfer between the two electrodes (302) and (306). A partial list of the appropriate nanoparticle materials for the collector electrode (306) is provided elsewhere herein. In the exemplary embodiment, at least one layer of Au nanoparticles (not shown) is deposited (220) through electrospray onto the graphene film (332) to form a nanoparticle surface (310) on the graphene film (332). In at least one embodiment, the thickness of the layer of nanoparticles to form nanoparticle surface (332) is approximately 2 nm (i.e., the approximate thickness of a nanoparticle), where the 2 nm value should be considered non-limiting.

According to an embodiment, once the Au nanoparticle surface (310) is formed (220), the polymer base (334) is removed (222) using, e.g., an acetone solution, thereby rendering the polymer base (334) as a sacrificial material. Accordingly, the Au nanoparticle surface (310) on the graphene film (332) is ready to receive a thermionic emissive material thereon.

At least one layer of a thermionic electron emissive material (312) is deposited (224) on at least a portion of the Au nanoparticle surface (310). In an embodiment, the thermionic electron emissive material (312), which in exemplary embodiments is a monolayer of the thermionic electron emissive material (312), is deposited on over about at least 50% to about 70% of the surface of the Au nanoparticle surface (310). In another embodiment, about 60% of the surface of the Au nanoparticle surface (310) receives (a monolayer of) the material (312). In yet another embodiment, a plurality of layers of the thermionic electron emissive material (312) is deposited on about 60% of the Au nanoparticle surface (310). The deposited thermionic electron emissive material (312) is selected to decrease the work function value of the collector electrode (306) to a value below that of the work function value of the material selected for the Au nanoparticle surface (310). Referring to FIG. 4, the table (400) indicates that the work function value of Au is 5.1 eV. Deposition of Cs₂O (312) on the Au nanoparticle surface (310) decreases the work function value of the collector emitter electrode (306) to 0.65 eV. Accordingly, similar to the emitter electrode (302), in exemplary embodiments one or more metal materials in the form of nanoparticles are selected as the nanoparticle surface (310) for the collector electrodes (306) at least partially as a function of decreasing the work function value of the electrodes (302) and (306) and maintaining a work function value differential between the electrodes (302) and (306) above a predetermined value.

Fabrication of the Insulator Posts

Once the electrodes (302) and (306) are fabricated, the assembly (200) of the (nano-scale) energy conversion device (100)/(300) continues. Specifically, one of the collector electrode (306) (as shown in FIG. 3) and the emitter electrode (302) is positioned on a surface (not shown) for support. A template (not shown in FIG. 2) is employed to fabricate (226) a plurality of insulator posts (e.g., columns, standoffs, or micro-pillars) (314) through electrospray deposition to maintain separation between the electrodes (302) and (306) such that the electrodes (302) and (306) and the insulator posts (314) define a cavity (316). In at least one embodiment, the template is a graphite template. In an embodiment, the insulator posts (314) are fabricated with a dielectric material, such as, and without limitation, alkanethiol, sol-gel with aerogel-like properties, corona dope, super corona dope, silicon, silicon-oxide, polymer, or any dielectric material. The templates are constructed to allow for electro-spraying of the alkanethiol such that overspray onto the thermionic electron emissive materials (308) and (312) is minimized. In an embodiment, rather than insulator posts (314), one or more insulator walls are formed that divide the cavity (316) into multiple cavities (316).

In an embodiment, the height (318) of the insulator posts (314) is in a range of 1 nanometer (nm) to less than 10 nm. Therefore, in this embodiment, the cavity (316) extends between the electrodes (302) and (306) for a distance in the range from 1 nanometer (nm) to less than 10 nm. The width (320) of the insulator posts (314) ranges from 1 nanometer (nm) to 10 nm. In an embodiment, the cavity (316) has a width (322) in a range of 1 nanometer (nm) to 10 nm. The insulator posts (314) are shown as cubical or cubical like structures and substantially similar in shape and size to that of the cavity (316), although this configuration is not limiting. In an embodiment, the distance between insulator posts (314) is within a range of about 5-6 nm to about 1 cm. The dimensions and configurations of the insulator posts (314) and cavities (316) are determined based on the planned employment of the (nano-scale) energy conversion devices (100)/(300). Accordingly, in exemplary embodiments, insulator posts (314) (or walls) are fabricated on one of the two electrodes (302) and (306) at a predetermined height to maintain a predetermined distance between the two electrodes (302) and (306) within the (nano-scale) energy conversion device (100)/(300).

Coupling the Electrodes and Insulator Posts Together

The electrodes (302) and (306) and the insulator posts (314) are coupled (228) together. As described above, and shown in FIG. 3, the insulator posts (314) are deposited on the collector electrode (306). The electrode on which the insulator posts (314) were not formed, as shown in FIG. 3, the emitter electrode (302), is lowered to rest on top of the insulator posts (314) as shown by the arrows (326). An adhesive material (324), shown in FIG. 3 as a plurality of beads, is spot-deposited at the outside ends of the (nano-scale) energy conversion device (100)/(300) to adhere the electrodes (302) and (306) and insulator posts (314) as a unit. In an embodiment, this aspect of the assembly is completed when the device (100)/(300) is sealed or encased with one of silicon or silicon dioxide casing segments, a sealant such as a hot melt adhesive, or by electro-spraying an alkanethiol film gasket around the edge of the device on all sides. In an embodiment, one side remains unsealed to facilitate addition of a nanofluid (as discussed further elsewhere herein). The positioning of the electrodes (302) and (306) and the insulator posts (314) define a cavity (316) therebetween (230).

Manufacturing the Nanofluid and Adding the Nanofluid to the Cavities

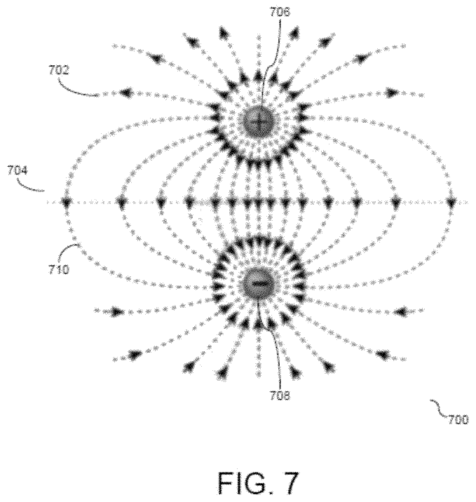

Referring to FIGS. 2A and 2B, the nanofluid (112) is manufactured (232). Referring to FIG. 8, a diagram is provided illustrating a cutaway view of one embodiment of a nanofluid (800) including a plurality of Au and Ag nanoparticle clusters (802) and (804), respectively, suspended in a dielectric medium (806). In FIG. 8, the clusters (802) and 804) are embodied as single nanoparticles. In some embodiments, and without limitation, the dielectric medium (806) is water, silicone oil, or alcohol. Also, in at least one embodiment, the dielectric medium (806) is a sol-gel with aerogel-like properties or an aerogel and low thermal conductivity values that reduce heat transfer therethrough, e.g., thermal conductivity values as low as 0.013 watts per meter-degrees Kelvin (W/m-° K) as compared to the thermal conductivity of water at 20 degrees Celsius (° C.) of 0.6 W/m-° K. Appropriate materials are selected prior to fabricating the nanoparticle clusters (802) and (804). According to an embodiment, material selected for the nanoparticle clusters (802) and (804) have work function values that are greater than the work function values for the electrodes (234). For example, the work function values of the Au nanoparticle clusters (802) and the Ag nanoparticle clusters (804) are 4.1 eV and 3.8 eV, respectively.

At least one layer of a dielectric coating, such as a monolayer of alkanethiol material (808), is deposited, e.g., electrosprayed, on the nanoparticles (236) to form a dielectric barrier thereon. The alkanethiol material at step (236) includes, but is not limited to, dodecanethiol and decanethiol. The deposit of the dielectric coating, such as alkanethiol, reduces coalescence of the nanoparticle clusters (802) and (804). In at least one embodiment, the nanoparticle clusters (802) and (804) have a diameter in the range of 1 nm to 3 nm. In an embodiment, the nanoparticle clusters (802) and (804) have a diameter of 2 nm. The nanoparticle clusters of Au (802) and Ag (804) are tailored to be electrically conductive with charge storage features (e.g., capacitive features), reduce or minimize heat transfer through the cavities (110) and (316) with low thermal conductivity values, reduce or minimize ohmic heating, reduce or eliminate space charges in the cavities (110) and (316), and reduce or prevent arcing. The plurality of Au and Ag nanoparticle clusters (802) and (804), respectively, are suspended (238) in the dielectric medium (806). Accordingly, the nanofluid (800), including the suspended nanoparticle clusters (802) and (804), provide a conductive pathway for electrons to travel across the cavities (110) and (316) from the emitter electrode (102) and (302) to the collector electrode (104) and (306) through charge transfer.

According to an embodiment, the Au nanoparticle clusters (802) are dodecanethiol functionalized gold nanoparticles, with a particle size of 1-3 nm, at about 2% (weight/volume percent) and suspended in toluene. In an embodiment, the Ag nanoparticle clusters (804) are dodecanethiol-functionalized silver nanoparticles, with a particle size of 1-3 nm, at about 0.25% (weight/volume percent) and suspended in hexane. In an embodiment, the particle size of both the Au and Ag nanoparticle clusters (802) and (804) is at or about 2 nm. The Au and Ag cores of the nanoparticle clusters (802) and (804) are selected for their abilities to store and transfer electrons. In an embodiment, a 50%-50% mixture of Au and Ag nanoparticle clusters (802) and (804) are used. However, a mixture in the range of 1-99% Au-to-Ag could be used as well. Electron transfers are more likely between nanoparticle clusters (802) and (804) with different work functions. In an embodiment, a mixture of nearly equal numbers of two dissimilar nanoparticle clusters (802) and (804) provides good electron transfer. Accordingly, nanoparticle clusters are selected based on particle size, particle material (with the associated work function values), mixture ratio, and electron affinity.

Conductivity of the nanofluid (800) can be increased by increasing concentration of the nanoparticle clusters (802) and (804). The nanoparticle clusters (802) and (804) may have a concentration within the nanofluid (800) of about 0.1 mole/liter to about 2 moles/liter. In at least one embodiment, the Au and Ag nanoparticle clusters (802) and (804) each have a concentration of at least 1 mole/liter.

The stability and reactivity of colloidal particles, such as Au and Ag nanoparticle clusters (802) and (804), respectively, are determined largely by a ligand shell formed by the alkanethiol coating (808) adsorbed or covalently bound to the surface of the nanoparticle clusters (802) and (804). The nanoparticle clusters (802) and (804) tend to aggregate and precipitate, which can be prevented by the presence of a ligand shell of the non-aggregating polymer alkanethiol coating (808) enabling these nanoparticle clusters (802) and (804) to remain suspended. Adsorbed or covalently attached ligands can act as stabilizers against agglomeration and can be used to impart chemical functionality to the nanoparticle clusters (802) and (804). Over time, the surfactant nature of the ligand coatings is overcome and the lower energy state of agglomerated nanoparticle clusters is formed. Therefore, over time, agglomeration may occur due to the lower energy condition of nanoparticle cluster accumulation and occasional addition of a surfactant may be used.

In an embodiment, the nanofluid (802) is loaded (240) into the cavities (110) and (316) by capillary and vacuum processes through the remaining unsealed side of the (nano-scale) energy conversion device (100)/(300). In an embodiment, assembly is completed when the remaining unsealed side of the (nano-scale) energy conversion device (100)/(300) is sealed (242) or encased with, for example, one of silicon or silicon dioxide casing segments, a sealant such as a hot melt adhesive, or by electrospraying an alkanethiol film gasket around the remaining unsealed side of the device. Accordingly, in at least one embodiment, a plurality of Au and Ag nanoparticle clusters (802) and (804), respectively, are mixed together in a dielectric medium (806) to form a nanofluid (112)/(800), the nanofluid (112)/(800) is inserted into the cavities (110)/(316), and the (nano-scale) energy conversion device (100)/(300) is fully sealed.

In an embodiment, the dimensions of the (nano-scale) energy conversion device (100)/(300) is approximately 20-50 mm long by approximately 20-50 mm wide by approximately 9-19 nm thick (e.g., about 4 nm for each electrode (102/302 and 104/306) and about 1 nm to less than about 10 nm for the cavity (110/316) therebetween). The thickness of the device (100/300) is determined based on the desired electron flow therein and the other two dimensions are scalable based on the desired overall power output of the device (100/300).

Principles of Operation of the (Nano-scale) Energy Conversion Device

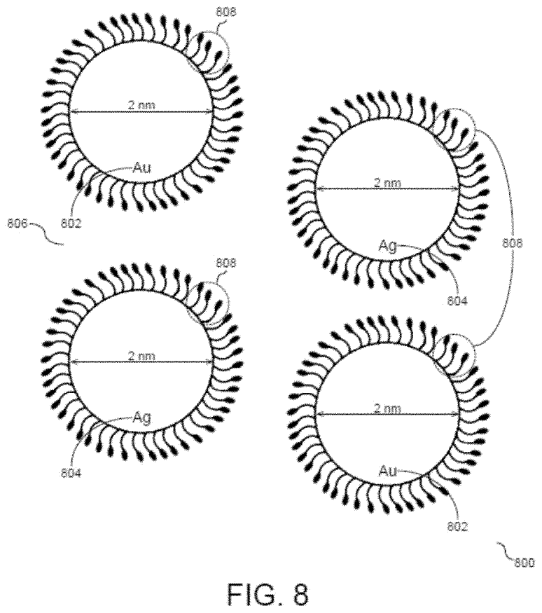

Referring again to FIG. 9, a flow chart is provided illustrating an embodiment of a process (900) for generating electric power with the energy conversion device (100), which in an embodiment is nano-scale. As described herein, an emitter electrode (102) is provided (902) and a collector electrode (104) is provided (904), where the work function value of the collector electrode (104) is different, and in an embodiment less, than the work function value of the emitter electrode (102). The emitter electrode (102) and the collector electrode (104) are positioned a predetermined distance from each other, e.g., about 1 nm to less than about 10 nm (906).

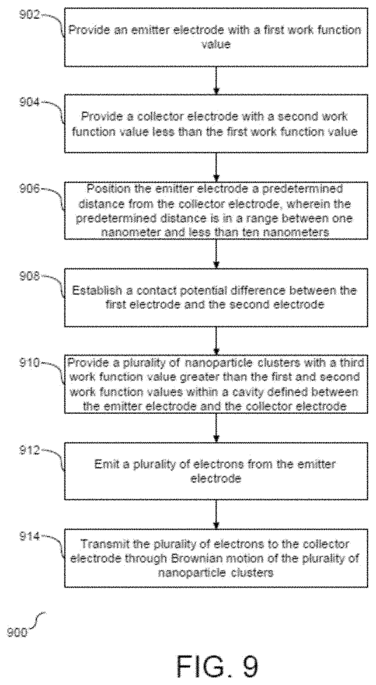

Referring to FIG. 10, a diagram is provided illustrating a cutaway view of an embodiment of the energy conversion device (1000) showing a relationship between the work functions of an emitter electrode (1002) (WFₑ), collector electrode (1004) (WF_{c}), and nanofluid (1006) (WF_{nf}) therein for the embodiment. FIG. 10 also shows a pair of insulator posts (1008) separating the electrodes (1002) and (1004). The difference between the WFₑ and WF_{c} establishes (908) a contact potential difference (CPD) between the two electrodes (1002) and (1004). Specifically, a voltage differential (V_{CPD}) is induced across the nanofluid (1006) due to the dissimilar metals of electrodes (1002) and (1004), e.g., W and Au, respectively, both including at least a monolayer, e.g., of Cs₂O over about 60% of the opposing surfaces thereof. In this embodiment, the value for WFₑ is 0.88 eV and the value for WF_{c} is 0.65 eV, to induce a V_{CPD} of 0.23 eV. The V_{CPD} induces an electric field (E_{CPD}) to be overcome to transmit electrons through the nanofluid (1006) from the emitter electrode (1002) to the collector electrode (1004). Accordingly, as described further herein, this induced CPD enables thermionic emission of electrons from the emitter electrode (1002) toward the collector electrode (1004).

In an embodiment, the nanofluid (1006) including a plurality of Au nanoparticle clusters (1010) and Ag nanoparticle clusters (1012) is provided (910). In this embodiment, the work functions of the Au nanoparticle clusters (1010) and Ag nanoparticle clusters (1012) are 4.1 eV and 3.8 eV, respectively. Therefore, a collective work function WF_{nf} is greater than WFₑ which is greater than WF_{c}. This relationship of the work function values of the Au and Ag nanoparticle clusters (1010) and (1012) optimizes the transfer of electrons to the nanoparticle clusters (1010) and (1012) through Brownian motion and electron hopping (discussed further herein). Accordingly, the selection of materials within the energy conversion device (1000) generates, and may optimize, electric current and transfer therein through enhancing the release of electrons from the emitter electrode (1002) and the conduction of the released electrons across the nanofluid (1006) to the collector electrode (1004).

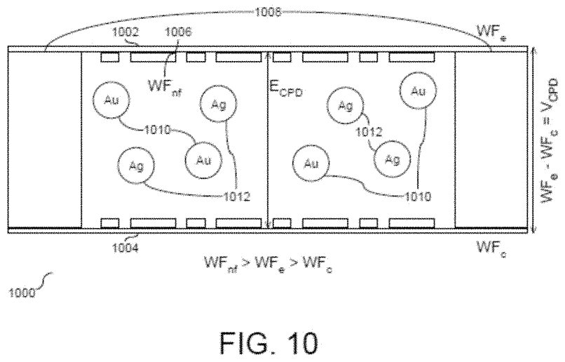

Referring to FIG. 11, a diagram is provided illustrating a graphical representation (1100) of the effect of the emitter work function value being larger than the collector work function value in accordance with an embodiment. The emitter electrode (1102) and the collector electrode (1104) are separated by the cavity (1106) that is filled with nanofluid (1108). A thermal distribution function (1110) of the electrons in the emitter electrode (1102) above the electrochemical potential (the Fermi level (μₑ)) as a function of the distance from the surface (1112) of the electrode (1102) is shown. The work function (WFₑ) of the emitter electrode (1102) extends from the Fermi level (μₑ) of the emitter electrode (1102) to an electrical potential of the emitter electrode (Eₑ). Similarly, a thermal distribution function (1114) of the electrons in the collector electrode (1104) above the electrochemical potential (the Fermi level (μ_{c})) as a function of the distance from the surface (1116) of the electrode (1104) is shown. The work function (WF_{c}) of the collector electrode (1104) extends from the Fermi level (μ_{c}) of the collector electrode (1104) to the electrical potential of the collector electrode (E_{c}). The Fermi level (μ_{c}) of the collector electrode (1104) is shifted upward due to the electrical potential of a load (eV_{load}) connected to the electrodes (1102) and (1104) inducing a contact potential difference voltage (V_{CPD}) across the cavity (1108), where eV_{load} and V_{CPD} are equal to each other. An electrical potential function (E) is shown declining from the surface (1112) of the emitter electrode (1102) to the surface (1116) of the collector electrode (1104), i.e., from Eₑ to E_{c} linearly as the electrons traverse the nanofluid (1106) and the cavity (1108) as indicated by the arrow (1118). The emitter work function (WFₑ) is greater than the collector work function (WF_{c}) in the embodiment so that electrons are accelerated toward the collector electrode (1104) and not accelerated back towards the emitter electrode (1102). Accordingly, the selection of the materials for the emitter electrode (1102) and the collector electrode (1104) with the associated work function and Fermi level values determining operational functionality of the energy conversion device (100).

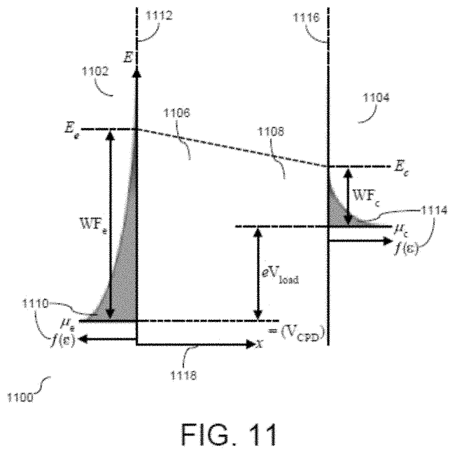

Referring to FIG. 12 (and FIGS. 1 and 9), a diagram (1200) is provided illustrating electron transfer through collisions of a plurality of nanoparticle clusters. As shown in FIG. 12, the nanofluid (1202) includes a plurality of nanoparticle clusters (1204), each embodied as a nanoparticle, suspended in a dielectric medium (1206). In the embodiment shown, the plurality of nanoparticle clusters (1204) includes Au nanoparticle clusters (1208) and Ag nanoparticle clusters (1210), each embodied as a nanoparticle. The Au nanoparticle clusters (1208) have a work function value of about 4.1 eV and the Ag nanoparticle clusters (1210) have a work function value of about 3.8 eV. In an embodiment, these work function values of the nanoparticle clusters (1204) are much greater than the work function values of the emitter electrode (102) (0.88 eV) and the collector electrode (104) (0.65 eV). The nanoparticle clusters (1204) are coated with a dielectric such as alkanethiol to form a dielectric barrier (1212) thereon to reduce coalescence of the nanoparticle clusters (1204). In an embodiment, the nanoparticle clusters (1204) have a diameter of about 2 nm. The nanoparticle clusters (1204) are tailored to be electrically conductive with capacitive (i.e., charge storage) features while minimizing heat transfer therethrough. Accordingly, suspended nanoparticle clusters (1204) provide a conductive pathway for electrons to travel across the cavity (110) from the emitter electrode (102) to the collector electrode (104) through charge transfer.

Thermally-induced Brownian motion causes the nanoparticle clusters (1204) to move within the dielectric medium (1206), and during this movement they occasionally collide with each other and with the electrodes (102) and (104). As the nanoparticle clusters (1204) move and collide within the dielectric medium (1206), the nanoparticle clusters (1204) chemically and physically transfer charge. The nanoparticle clusters (1204) transfer charge chemically when electrons (1214) hop from the electrodes (102) and (104) to the nanoparticle clusters (1204) and from one nanoparticle cluster (1204) to another nanoparticle. The hops primarily occur during collisions. Due to differences in work function values, electrons (1214) are more likely to move from the emitter electrode (102) to the collector electrode (104) via the nanoparticle clusters (1204) rather than in the reverse direction. Accordingly, in exemplary embodiments a net electron current from the emitter electrode (102) to the collector electrode (104) via the nanoparticle clusters (1204) is the primary and dominant current of the (nano-scale) energy conversion device (100).

The nanoparticle clusters (1204) transfer charge physically (e.g., undergo transient charging) due to the ionization of the nanoparticle clusters (1204) upon receipt of an electron and the electric field generated by the differently charged electrodes (102) and (104). The nanoparticle clusters (1204) become ionized in collisions when they gain or lose an electron (1214). Positive and negative charged nanoparticle clusters (1204) in the nanofluid (1202) migrate to the negatively charged collector electrode (104) and the positively charged emitter electrode (102), respectively, providing a current flow. This ion current flow is in the opposite direction from the electron current flow, but much less in magnitude than the electron flow.

Some ion recombination in the nanofluid (1202) may occur, which diminishes both the electron and ion current flow. Electrode separation may be selected at an optimum width to maximize ion formation and minimize ion recombination. In an exemplary embodiment, the electrode separation is slightly less than 10 nm. The nanoparticle clusters (1204) have a maximum dimension of about 2 nm, so the electrode separation is about 3 to 5 nanoparticle clusters (1204). This separation distance provides sufficient space within the cavity for nanoparticle clusters (1204) to move around and collide, while minimizing ion recombination. For example, in an embodiment, an electron can hop from the emitter electrode (102) to a first nanoparticle cluster (1204) and then to a second, third, fourth, or fifth nanoparticle cluster (1204) before hopping to the collector electrode (104). A reduced quantity of hops mitigates ion recombination opportunities. Accordingly, ion recombination in the nanofluid (1202) can be minimized through an electrode separation distance selected at an optimum width to maximize ion formation and minimize ion recombination.

In an embodiment, when the emitter electrode (102) and the collector electrode (104) are initially brought into close proximity, the electrons of the collector electrode (104) have a higher Fermi level than the electrons of the emitter electrode (102) due to the lower work function of the collector electrode (104). The difference in Fermi levels drives a net electron current that transfers electrons from the collector electrode (104) to the emitter electrode (102) until the Fermi levels are equal, i.e., the electrochemical potentials are balanced and thermodynamic equilibrium is achieved. The transfer of electrons between the emitter electrode (102) and the collector electrode (104) results in a difference in charge between the emitter electrode (102) and the collector electrode (104). This charge difference sets up the voltage of the contact potential difference (V_{CPD}) and an electric field between the emitter electrode (102) and the collector electrode (104), where the polarity of the V_{CPD} is determined by the material having the greatest work function. With the Fermi levels equalized, no net current will flow between the emitter electrode (102) and the collector electrode (104). Accordingly, electrically coupling the emitter electrode (102) and the collector electrode (104) with no external load results in attaining the contact potential difference between the electrodes (102) and (104) and no net current flow between the electrodes (102) and (104) due to attainment of thermodynamic equilibrium between the two electrodes (102) and (104).

The (nano-scale) energy conversion device (100) can generate electric power (e.g., at room temperature) with or without additional heat input. Heat added to the emitter electrode (102) will raise its temperature and the Fermi level of its electrons. With the Fermi level of the emitter electrode (102) higher than the Fermi level of the collector electrode (104), a net electron current will flow from the emitter electrode (102) to the collector electrode (104) through the nanofluid (1202). If the external circuit (128) is connected, the same amount of electron current flows through the external circuit current (134) from the collector electrode (104) to the emitter electrode (102). The heat energy added to the emitter electrode (102) is carried by the electrons (1214) to the collector electrode (102). The bulk of the added energy is transferred to the external circuit (128) for conversion to useful work and some of the added energy is transferred in collisions to the collector electrode (104) and eventually lost to ambient as waste energy. As the energy input to the emitter electrode (102) increases, the temperature of the electrode (102) increases, and the electron transmission from the emitter electrode (102) increases, thereby generating more current. As the emitter electrode (102) releases (912) electrons onto the nanoparticle clusters (1204), energy is stored in the (nano-scale) energy conversion device (100). Accordingly, the (nano-scale) energy conversion device (100) generates, stores, and transfers charge and moves heat energy if a temperature difference exists, where added thermal energy causes the production of electrons to increase from the emitter electrode (102) into the nanofluid (1202).

The nanofluid (1202) is used to transfer charges from the emitter electrode (102) to one of the mobile nanoparticle clusters (1204) (via intermediate contact potential differences) from the collisions of the nanoparticle cluster (1204) with the emitter electrode (102) induced by Brownian motion (914) of the nanoparticle cluster (1204). In an embodiment, the selection of dissimilar nanoparticle clusters (1204) that include Au nanoparticle clusters (1208) and Ag nanoparticle clusters (1210) that have much greater work functions of about 4.1 eV and about 3.8 eV, respectively, optimizes transfer of electrons to the nanoparticle clusters (1204) from the emitter electrode (102) and to the collector electrode (104).

As the electrons (1214) hop from one nanoparticle cluster (1204) to another nanoparticle cluster (1204), single electron charging effects that include the additional work required to hop another electron (1214) on to a nanoparticle cluster (1204) if an electron (1214) is already present on the nanoparticle cluster (1204) determine if hopping additional electrons (1214) onto that particular nanoparticle cluster (1204) is possible. Specifically, the nanoparticle clusters (1204) include a voltage feedback mechanism that prevents the hopping of more than a predetermined number of electrons to the nanoparticle cluster (1204). This prevents more than the allowed number of electron(s) from residing on the nanoparticle cluster simultaneously. In an embodiment, only one electron (1214) is permitted on any nanoparticle cluster (1204) at any one time. Therefore, during conduction of current through the nanofluid (1202), a single electron (1214) hops onto the nanoparticle cluster (1204). The electron (1214) does not remain on the nanoparticle cluster (1204) indefinitely, but hops off to either the next nanoparticle cluster (1204) or the collector electrode (104) through collisions resulting from the Brownian motion of the nanoparticle clusters (1204). However, the electron (1214) does remain on the nanoparticle cluster (1204) long enough to provide the voltage feedback to prevent additional electrons (1214) from hopping simultaneously onto the nanoparticle cluster (1204). The hopping of electrons (1214) across the nanoparticle clusters (1204) avoids resistive heating associated with current flow in a media.

Notably, in an exemplary embodiment, the (nano-scale) energy conversion device (100) does not require pre-charging by an external power source in order to introduce electrostatic forces. This is due to the device (100) being self-charged with triboelectric charges generated upon contact between the nanoparticle clusters (1204) due to Brownian motion. Accordingly, in an embodiment, the electron hopping across the nanofluid (1202) is limited to one electron (1214) at a time residing on a nanoparticle cluster (1204).

As the electrical current starts to flow through the nanofluid (1202), a substantial energy flux away from the emitter electrode (102) is made possible by the net energy exchange between the emitted (1214) and replacement electrons. The replacement electrons from the second electrical conductor (132) connected to the emitter electrode (102) do not arrive with a value of energy equivalent to an average value of the Fermi energy associated with the material of emitter electrode (102), but with an energy that is lower than the average value of the Fermi energy. Therefore, rather than the replacement energy of the replacement electrons being equal to the chemical potential of the emitter electrode (102), the electron replacement process takes place in the available energy states below the Fermi energy in the emitter electrode (102). The process through which electrons are emitted above the Fermi level and are replaced with electrons below the Fermi energy is sometimes referred to as an inverse Nottingham effect. In an embodiment, the low work function value of, for example, about 0.88 eV for the emitter electrode (102), allows for the replacement of the emitted electrons with electrons with a lower energy level to induce a cooling effect on the emitter electrode (102).

As described this far, in embodiments the principle electron transfer mechanism for operation of the (nano-scale) energy conversion device (100) is thermionic energy conversion or harvesting. In some embodiments, thermoelectric energy conversion is conducted in parallel with the thermionic energy conversion. In at least one of such embodiments, either the emitter electrode (102) or the collector electrode (104), or both, include at least one material selected from lead selenide telluride (PbSeTe) and/or lead telluride (PbTe). PbSeTe and PbTe are thermoelectric conversion materials that, when introduced into the emitter electrode (102), allows for emission of electrons from the emitter electrode (102) through thermoelectric electron emission. In some embodiments, the PbSeTe or PbTe is also introduced into the collector electrode (104) to multiply the number of electrons being introduced into the external circuit current (134). Similarly, in some embodiments, the PbSeTe or PbTe is introduced at least a portion of the suspended nanoparticle clusters (1204) to multiply the number of electrons being introduced into the external circuit current (134). For example, an electron (1214) colliding with a nanoparticle cluster (1204) with a first energy may induce the emission of two electrons at second and third energy levels, respectively, where the first energy level is greater than the sum of the second and third energy levels. In such circumstances, the energy levels of the emitted electrons are not as important as the number of electrons. Accordingly, the introduction of the PbSeTe or PbTe as described herein in accordance with certain embodiments increases conversion of thermal energy to electrical energy through further increasing the rate of transfer of electrons through the (nano-scale) energy conversion device (100).

Furthermore, the PbSeTe or PbTe used as described herein may be an n-type compound doped with a transition metal in the form of bismuth (Bi) or antimony (Sb). The doping of the n-type compound of PbSeTe or PbTe with the transition metal further increases conversion of thermal energy to electrical energy through further increasing the rate of transfer of electrons through the (nano-scale) energy conversion device (100). Accordingly, introducing PbSeTe or PbTe, doped with, or, without the transition metal into the emitter electrode (102), the collector electrode (104), and the nanoparticle clusters (1204), increases conversion of thermal energy to electrical energy through increasing the rate of transfer of electrons through the (nano-scale) energy conversion device (100).

A plurality of (nano-scale) energy conversion devices (100) are distinguished by at least one embodiment having the thermoelectric energy conversion features described herein. In general, the nanofluid (1202) is selected for operation of the (nano-scale) energy conversion devices (100) within more than one temperature range. In an embodiment, the temperature range of the associated (nano-scale) energy conversion device (100) is controlled to modulate a power output of the device (100). In general, as the temperature of the emitter electrode (102) increases, the rate of thermionic emission therefrom increases. The operational temperature ranges for the nanofluid (1202) are, in an exemplary embodiment, based on the desired output of the (nano-scale) energy conversion device (100), the temperature ranges that optimize thermionic conversion, the temperature ranges that optimize thermoelectric conversion, and fluid characteristics. Therefore, different embodiments of the nanofluid (1202) are designed for different energy outputs of the device (100). For example, for the nanofluid (1202), when the dielectric medium (1206) is silicone oil, the temperature of the nanofluid (1202) should be maintained at less than 250° C. to avoid deleterious changes in energy conversion due to the viscosity changes of the silicone oil above 250° C. In an embodiment, the temperature range of the nanofluid (1202) for substantially thermionic emission only is approximately room temperature (i.e., about 20° C. to about 25° C.) up to about 70-80° C., and the temperature range of the nanofluid for thermionic and thermo-electric conversion is above 70-80° C., with the principle limitations in embodiments being the temperature limitations of the materials. In an embodiment, the nanofluid (1202) for operation including thermoelectric conversion includes a temperature range that optimizes the thermoelectric conversion through optimizing the power density within the (nano-scale) energy conversion device (100), thereby optimizing the power output of the device (100). In at least one embodiment, a mechanism for regulating the temperature of the first nanofluid (1202) includes diverting some of the energy output of the device (100) into the nanofluid (1202). Accordingly, the cavities (110) of specific embodiments of the (nano-scale) energy conversion device (100) may be filled with the nanofluid (1202) to employ thermoelectric energy conversion with thermionic energy conversion above a particular temperature range, or thermionic energy conversion by itself below that temperature range.

As described elsewhere herein, in at least one embodiment, the dielectric medium (1206) has thermal conductivity values less than about 1.0 watts per meter-degrees Kelvin (W/m-K). In at least one embodiment, the thermal conductivity of the dielectric medium (1206) is as low as about 0.013 watts per meter-degrees Kelvin (W/m ° K), as compared to the thermal conductivity of water at about 20 degrees Celsius (° C.) of 0.6 W/m·K. Accordingly, the first nanofluid (1202) reduces or minimizes heat transfer through the cavity (110) with low thermal conductivity values. Since the heat transport in a low thermal conductivity first nanofluid (1202) can be small, a high temperature difference between the two electrodes (102) and (104) can be maintained during operation. These embodiments are particularly designed for those (nano-scale) energy conversion devices (100) that employ thermionic emission only, where minimal heat transfer through the first nanofluid (1202) is desired.

In some alternative embodiments of (nano-scale) energy conversion devices (100), greater heat transfer through the nanofluid (1202) is desired. In exemplary embodiments, the (nano-scale) energy conversion device (100) has a cavity (110) dimension of less than about 10 nm. In this predetermined distance range of about 1 nm to less than about 10 nm, thermal conductivity values and electrical conductivity values of the first nanofluid (1202) are enhanced over thermal and electrical conductivity values of the first nanofluid (1202) when the predetermined distance of the cavity is greater than about 100 nm. This increase of thermal and electrical conductivity values of the nanofluid (1202) is due to a number of factors. The first factor is that of enhanced phonon and electron transfer between the plurality of nanoparticle clusters (1204) within the nanofluid (1202), enhanced phonon and electron transfer between the plurality of nanoparticle clusters (1204) and the first electrode (102), and enhanced phonon and electron transfer between the plurality of nanoparticle clusters (1204) and the second electrode (104). A second factor is the enhanced influence of Brownian motion of the nanoparticle clusters (1204) in the more confining volume seen in the scale of less than about 10 nm. As the distance between electrodes (106) decreases below about 10 nm, the fluid continuum characteristics of the nanofluid (1202) with the suspended nanoparticle clusters (1204) is altered. For example, as the ratio of particle size to volume of the cavity (110) increases, the random and convection like effects of Brownian motion in a dilute solution dominate. Therefore, collisions of the nanoparticle clusters (1204) with the surfaces of other nanoparticle clusters (1204) and the electrodes (102) and (104) increase thermal and electrical conductivity values due to the enhanced phonon and electron transfer. A third factor is the at least partial formation of nanoparticle cluster (1204) matrices within the nanofluid (1202). In an embodiment, the formation of the matrices are based on the factors of time and/or concentration of the nanoparticle clusters (1204) in the nanofluid (1202). Under certain conditions, the nanoparticle clusters (1204) will form matrices within the nanofluid (1202) as a function of close proximity to each other with some of the nanoparticle clusters (1206) remaining independent from the matrices. A fourth factor is the predetermined nanoparticle cluster (1204) density, which in one embodiment is about one mole per liter. Accordingly, the very small dimensions of the cavity (110) of less than about 10 nm causes an increase in the thermal and electrical conductivity values of the nanofluid (1202) therein.

In addition, the nanoparticle clusters (1204) are extremely thin and they are often considered to have only one dimension, e.g., their characteristic length. This extreme thinness restricts electrons and holes in a process called quantum confinement, which increases electrical conductivity. The collision of particles with different quantum confinement facilitates transfer of charge to the electrodes (102) and (104). A nanoparticle cluster's (1204) small size also increases the influence of its surfaces, thereby tending to increase thermal conductivity. The embodiments of (nano-scale) energy conversion device (100) have an enhanced electrical conductivity value greater than about 1 Siemens per meter (S/m). Also, the embodiments of device (100) with the enhanced thermal conductivity have a thermal conductivity value greater than about 1 W/m-° K.

The thermionic emission of electrons (1214) from the emitter electrode (102) and the transfer of the electrons (1214) across the nanofluid (1202) from nanoparticle cluster (1204) to nanoparticle cluster (1204) through hopping are both quantum mechanical effects.

The release of electrons from the emitter electrode (102) through thermionic emission as described herein is an energy selective mechanism. A Coulombic barrier in the cavity (110) between the emitter electrode (102) and the collector electrode (104) is induced through the interaction of the nanoparticles (1204) with the electrodes (102) and (104) inside the cavity (110). The Coulombic barrier is at least partially induced through the number and material composition of the plurality of nanoparticle clusters (1204). The Coulombic barrier induced through the nanofluid (1202) provides an energy selective barrier on the order of magnitude of about 1 eV. Accordingly, the nanofluid (1202) provides an energy selective barrier to electron emission and transmission.

To overcome the Coulombic barrier and allow electrons (1214) to be emitted from the emitter electrode (102) above the energy level needed to overcome the barrier, the materials for the emitter electrode (102) and the collector electrode (104) are selected for their work function values and Fermi level values. The Fermi levels of the two metal electrodes (102) and (104) and the nanoparticle cluster (1204) will try to align by tunneling electrons (1214) from the electrodes (102) and (104) to the nanoparticle cluster (1204). The difference in potential between the two electrodes (102) and (104) (described elsewhere herein) overcomes the Coulombic barrier and the thermionic emission of electrons (1214) from the emitter electrode (102) occurs with sufficient energy to overcome the Coulombic block. Notably, for cooling purposes, removing higher energy electrons from the emitter electrode (102) causes the emission of electrons (1214) to carry away more heat energy from the emitter electrode (102) than is realized with lower energy electrons. Accordingly, the energy selective barrier is overcome through the thermionic emission of electrons at a higher energy level than would be otherwise occurring without the Coulombic barrier.

Once the electrons (1214) have been emitted from the emitter electrode (102) through thermionic emission, the Coulombic barrier continues to present an obstacle to further transmission of the electrons (1214) through the nanofluid (1202). Smaller gaps on the order of about, e.g., 1-10 nm facilitates electron hopping, i.e., field emission, of short distances across the cavity (110). In an embodiment, the energy requirements for electron hopping are much lower than the energy requirements for thermionic emission; therefore, the electron hopping has a significant effect on the energy generation characteristics of the device (100). The design of the nanofluid (1202) enables energy selective tunneling (hopping) that is a result of the special form of the barrier (which has wider gap for low energy electrons) which results in electrons above the Fermi level being the principal hopping component. The direction of the electron hopping is determined through the selection of the different materials for the electrodes (102) and (104) and their associated work function and Fermi level values. The electron hopping across the nanofluid (1202) transfers heat energy with electrons (1214) across the cavity (110) while maintaining a predetermined temperature gradient such that the temperature of the fluid (1214) is relatively unchanged during the electron transfer. Accordingly, the emitted electrons transport heat energy from the emitter electrode (102) across the cavity (110) to the collector electrode (104) without increasing the temperature of the nanofluid (1202).

Sample Applications of the (Nano-Scale) Energy Conversion Devices

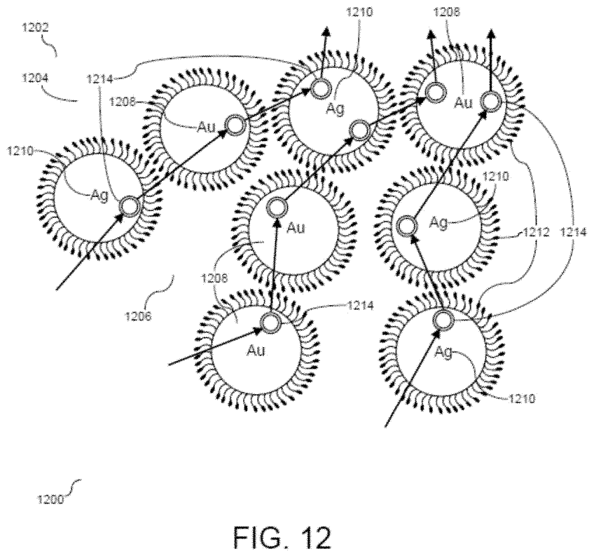

Referring to FIG. 13, a diagram is provided illustrating an embodiment of employment of the (nano-scale) energy conversion device (1300). Heat energy (1302) from a source enters the emitter electrode (1304). Electrons (1306) are thermionically emitted (1318) from the emitter electrode (1304). The electrons (1306) traverse the cavity (1308) that is filled with nanofluid (1310) as described herein. The electrons (1306) reach (1320) the collector electrode (1312) that collects the electrons (1306) to generate an output electron current (1314) that is transmitted through a first electrical conductor (1322) to a load (1316) to perform work. Electron current (1314) is transmitted from the load (1316) to the emitter electrode (1304) through a second electrical conductor (1324). Accordingly, the (nano-scale) energy conversion device (1300) harvests heat energy (1302), including waste heat and ambient heat, to generate electrical power (1314).

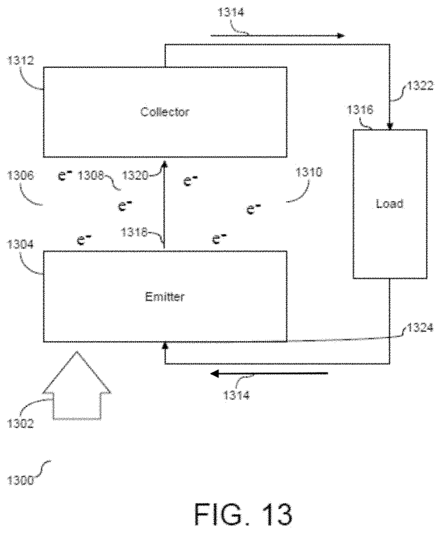

Referring to FIG. 14, a diagram is provided illustrating an embodiment of a system (1400) of stacked or grouped (nano-scale) energy conversion devices (1402) that generates electric power from heat (1404), which in one embodiment is waste heat or waste heat by-product. The system (1400) includes a plurality of (nano-scale) energy conversion devices (or cells) (1402) within an insulated casing (1406). In an embodiment, each (nano-scale) energy conversion device (1402) is capable of producing at least 0.024 watts/cell. In an embodiment, the system (1400) can reach a power density of about 1550 watts/liter by employing about 64,583 devices (1402) in this embodiment. As another example of usage of this particular embodiment, for a particular residential dwelling that uses 3 kilowatts (kW), therefore to power a typical home the system (1400) would require about a 2-liter system in this embodiment. Stacked (nano-scale) energy conversion devices (1402) (in series or in parallel) define the power flux to obtain an electric power system of desired current and voltage characteristics. In addition, heat removal capabilities are enhanced through the additional devices (1402). Accordingly, the (nano-scale) energy conversion devices (1402) are scalable and configurable to provide electric power under a variety of uses.

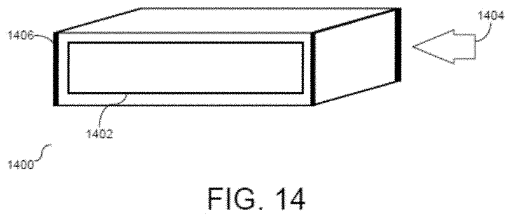

Referring to FIG. 15, a diagram is provided illustrating an embodiment of a waste heat harvesting system (1500) that includes a (nano-scale) energy conversion group (1502) coupled to an electronic chip (1504), such as a semi-conductor chip. The group (1502) harvests electrical energy from waste heat from the electronic chip (1504). Such a system (1500) is suitable for use in mobile phones and other portable electronic devices. The electronic chip (1504) is affixed to the (nano-scale) energy conversion group (1502) with an adhesive (1506), e.g., without limitation, an epoxy adhesive. The group of stacked (nano-scale) energy conversion devices (1502) includes, e.g., and without limitation, about 35 stacked (nano-scale) energy conversion devices. In an embodiment, the quantity of stacked (nano-scale) energy conversion devices may range depending on the size and dimensions of the semi-conductor chip. For example, in an embodiment, the quantity may range from a minimum of 1 to in excess of 1,000 stacked (nano-scale) energy conversion devices. Similarly, in an embodiment, the stacking of multiple (nano-scale) energy conversion devices forms layers thereof. In an embodiment, the (nano-scale) energy conversion group (1502) is cooled by both radiation heat transfer (1508) and natural convection heat transfer (1510). In an embodiment, the (nano-scale) energy conversion group (1502) is driven by a temperature difference where the electronic chip (1504) is operating at about 100° C. The harvested electrical power does not need to be used to cool the system (1500). The (nano-scale) energy conversion group (1502) includes a predetermined number of (nano-scale) energy conversion devices for multiplying currents and voltages as necessary. Accordingly, a (nano-scale) energy conversion group (1502) can be cooled by combined natural convection and radiation, and there may be no need to install any power-consuming fluid movers.

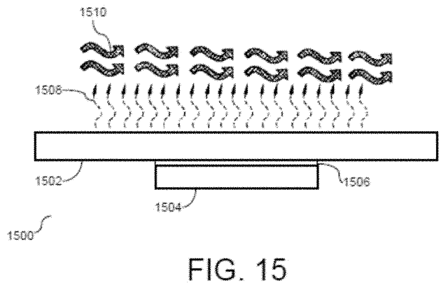

Referring to FIG. 16, a diagram is provided illustrating an embodiment of an electric power generation system (1600) that includes an array (1602) of (nano-scale) energy conversion devices (1604) coupled to an array of solar cells (1606) that harvests electrical energy from heat byproduct (1608) from the solar cell array (1606). An energy storage device (1610), such as, and without limitation, an ultra-capacitor, is electrically connected to the array (1602) of (nano-scale) energy conversion devices (1604). Integration of the (nano-scale) energy conversion devices (1604) into electric power generation system (1600) allows the array (1602) to both cool the solar cell array (1606) and synergistically generate power to augment photovoltaic production. In addition to enhancing photovoltaic power generation, the integration of the (nano-scale) energy conversion devices (1604) augments other thermal power sources such as hot water, geothermal sources, and automotive waste heat sources, to enhance the generation of electrical power. Accordingly, the (nano-scale) energy conversion devices (1604) can be integrated with multiple energy-harvesting devices to produce a greater energy-density device that would otherwise not be accomplished without the integration.

As described herein, embodiments of the present disclosure are directed generally to an ultra-long life energy source, such as a battery, and more particularly is directed to a (nano-scale) energy conversion device. Ionization is provided therein by the combination of electron tunneling and thermionic emission of the (nano-scale) energy conversion device. In embodiments, charge transfer therein is effected through conductive nanoparticles suspended in a fluid (e.g., a nanofluid) undergoing collisions driven by thermally-induced Brownian motion. The design of embodiments of the device enables ambient energy extraction at low and elevated temperatures (including room temperature). To this end, the electrodes are very close to each other to allow electrons to travel the distance between them. These electrons emitted at a wide range of temperatures proceed across the gap due to the nanofluid providing a conductive pathway for electrons, minimizing heat transfer to maintain a nanoscale heat engine, and preventing arcing. With respect to thermionic converters, in embodiments the electrical efficiency of these devices depends on the very low work function materials deposited on the emitter electrode (cathode) and the collector electrode (anode). The efficiency of two low work function electrodes can be increased by developing emitter electrodes (cathodes) with sufficient thermionic emission of electrons operating even at room temperature. In exemplary embodiments, the low work function emitter electrodes (cathodes) and collector electrodes (anodes) provide copious amounts of electrons. Similarly, a tunneling device involves two low work function electrodes separated by a designed nanofluid. Cooling by electrode emission refers to the transport of hot electrons across the nanofluid gap, from the object to be cooled (emitter electrode) to the heat rejection electrode (collector electrode). Thus, exemplary embodiments involve the coupling of several technologies, including: the electrospray-deposited low work function electrodes include cesium-oxide on, for example, both tungsten and gold; an energy selective electron-transfer thermionic emission and quantum hopping of electrons; a nanofluid that is tailored as a thermoelectric element to conduct electricity while minimizing heat transfer within the device; and thermal communication from the anode electrical connection that is in thermal contact with the device and the outside heat reservoir, produces a viable thermionic power generator.

The (nano-scale) energy conversion devices described herein facilitate generating electrical energy via a long-lived, constantly-recharging, battery for any size-scale electrical application. In exemplary embodiments, the devices provide a battery having a conversion efficiency superior to presently available single and double conversion batteries. In addition, embodiments of the devices described herein may be fabricated as an integral part of, and provide electrical energy for, an integrated circuit. In embodiments, the devices described herein are a light-weight and compact multiple-conversion battery having a relatively long operating life with an electrical power output at a useful value. Furthermore, in addition to the tailored work functions, the nanoparticle clusters described herein are, in embodiments, multiphase nanocomposites that include thermoelectric materials. The combination of thermoelectric and thermionic functions within a single device in one or more embodiments further enhances the power generation capabilities of the (nano-scale) energy conversion devices.

The conversion of ambient heat energy into usable electricity enables energy harvesting capable of offsetting, or even replacing, the reliance of electronics on conventional power supplies, such as electrochemical batteries, especially when long-term operation of a large number of electronic devices in dispersed locations is required. Energy harvesting distinguishes itself from batteries and hardwire power owing to inherent advantages, such as outstanding longevity measured in years, little maintenance, and minimal disposal and contamination issues. Embodiments of the (nano-scale) energy conversion devices described herein demonstrate a novel electric generator with low cost for efficiently harvesting thermal energy (without the need for an initial temperature differential or thermal gradient to start the electron flow).

Embodiments of the energy conversion devices described herein are scalable across a large number of power generation requirements. Embodiments of the devices may be designed for applications requiring electric power in the milliwatts (mW), watts (W), kilowatts (kW), and megawatts (MW) ranges. Examples of devices for the mW range include, but are not limited to, those devices associated with the Internet of Things (IoT) (home appliances, vehicles (communication only)), handheld portable electronic devices (mobile phones, medical devices, tablets), and embedded systems (RFIDs and wearables). Examples of devices for the watts range include, but are not limited to, handheld sensors, networks, robotic devices, cordless tools, drones, appliances, toys, vehicles, utility lighting, and edge computing. Examples of devices in the kW range include, but are not limited to, residential off-grid devices (rather than backup fossil fuel generators), resilient/sustainable homes, portable generators, electric and silent transportation (including water-faring), and spacecraft. Examples of devices in the MW range include, but are not limited to, industrial/data center/institutional off-grid devices (e.g., uninterruptible power supplies), resilient complexes, urban centers, commercial and military aircraft, flying cars, and railway/locomotive/trucking/shipboard transportation. Accordingly, substantially any power demand in any situation can be met with embodiments of the devices disclosed herein.

Aspects of the present embodiments are described herein with reference to one or more of flowchart illustrations and/or block diagrams of methods and apparatus (systems) according to the embodiments.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments. The embodiments were chosen and described in order to best explain the principles of the embodiments and the practical application, and to enable others of ordinary skill in the art to understand the embodiments for various embodiments with various modifications as are suited to the particular use contemplated. The implementation of the (nano-scale) energy conversion devices as heat harvesting devices that efficiently convert waste heat energy to usable electric energy facilitates flexible uses of the minute power generators. Accordingly, the (nano-scale) energy conversion devices and the associated embodiments as shown and described in FIGS. 1-16, provide electrical power through conversion of heat in most known environments, including ambient, ambient temperature environments.

It will be appreciated that, although specific embodiments have been described herein for purposes of illustration, various modifications may be made without departing from the spirit and scope of the embodiments. In particular, the (nano-scale) energy conversion devices are shown as configured to harvest waste heat from stationary or relatively stationary conditions. Alternatively, the (nano-scale) energy conversion devices may be configured to harvest waste heat while in motion. Accordingly, the scope of protection of the embodiment(s) is limited only by the following claims and their equivalents.

Harvesting naturally occurring energy is increasingly important to support global power demands. For example, kinetic energy can be converted to electrical energy via the use of material properties and quantum physics. The converted electrical energy may be used for powering appliances, vehicles, and buildings. Energy conversion devices may increase their appeal and utilization by increasing their specific power and power density. Specific power of a device is measured as the power output of the device divided by its mass (e.g., W/kg). Power density of a device is measured as the power output per unit volume (e.g., W/m³). Maximizing the specific power and the power density of a device is critical to powering components and systems that utilize the energy conversion device.

The specific power and power density of a device may be maximized through improved energy conversion physics. For example, varying the thickness of the insulating material positioned between an emitter and a collector varies the specific power and power density of the device. But the specific power and power density may also be improved by increasing the compactness of the energy conversion device. For example, increasing the number of emitter and collector electrodes within a fixed space increases the specific power and power density of the energy conversion device. The specific power and power density directly describe the mass and volume efficiency of the energy conversion device. The mass and volume efficiency are critical parameters at the system and vehicle design level for a vehicle or other components that utilize such a device.

As the metrics suggest, each of the metrics may be improved in at least two manners: power production improvement (e.g., kinetic energy to electrical energy conversion) or compactness (mass or volume) of the device. To date, a majority of technology development of such devices has focused on power production improvement while the compactness of the architecture of the devices has remained relatively unchanged. Specifically, the conventional device architecture consists of a single cell that includes an emitter, a transport medium (which may take many forms but is usually in the form of a vacuum), and a collector. The single cell is repeated to scale the output for larger magnitude applications. This repeating architecture is inefficient from a compactness standpoint and may limit the scalability of the conversion device.

Disclosed herein are improved architectural approaches and compositions of matter for an energy conversion device. The architectural approaches improve upon the compactness of the architecture by using a stacked architecture for the device. The compositions of matter improve the power conversion of the device by taking advantage of charge carrier interaction. The device architecture disclosed herein may be configured pursuant to at least three features: (1) a multilayered monolithic architecture that allows both sides of the electrodes to be used for emission/collection, having thermal/electrical interfaces positioned on side(s) of the device instead of the top/bottom as in conventional devices; (2) compositions of matter facilitating charge carrier interaction for improved power conversion; and (3) methods that enable the use of thinner components in the device. Such features provide significant improvement to specific power and power density for energy conversion devices. The aforementioned approach leads to improved specific power and power density that make viable new applications for energy conversion technology.

The energy conversion device may be configured according to a stacked architecture. The stacked architecture may include alternating layers of electrodes and transport medium material. More specifically, the stacked architecture includes emitter electrodes and collector electrodes with the collector electrodes separating each set of the emitter electrodes. The transport medium may separate each emitter electrode and collector electrode.

The energy conversion device may comprise a substrate. The substrate may be provided as a base for the stacked architecture. The substrate may include multiple layers bonded together. Layers in the substrate may include a thermal insulation layer, a sealant layer, a bonding layer, a structural layer, and an insulative layer. The substrate may be treated with a surface treatment to prevent energy loss. Optionally, the substrate may include a layer of semiconductor material upon which the stacked architecture is developed. In a non-limiting example implementation, the substrate may comprise polyimide, a polymethyldisiloxane, a polystyrene, an epoxy, a polypropylene, a poly(methylmethacrylate), a polyethylene, and a poly(vinyl chloride). In some embodiments, a layer comprising the substrate may include a continuous covering of atoms or nanoparticles across a surface. Alternatively, and/or additionally, the layer comprising the substrate may include atoms or nanoparticles dispersed across the surface with portions of the surface exposed.

In a non-limiting example implementation, the stacked architecture at least partially includes alternating emitter and collector electrodes, each having opposing sides and an isolated transport medium between each electrode. The stacking architecture enables both sides of each electrode to be used for emission/collection in the energy conversion process. In addition, the device includes thermal/electrical interfaces that are positioned on opposed sides of the device to thereby provide all of the electrodes with access to the thermal/electrical interfaces.

The device may be manufactured pursuant to nanoscale manufacturing processes. Additionally, the electrodes and any other necessary structural components may be manufactured pursuant to nanoscale manufacturing to make them much thinner than conventional energy conversion device manufacturing. Moreover, nanoscale manufacturing confers other benefits such as precise geometry definitions, more controlled chemistry, controlled roughness, tighter tolerances, and process repeatability.

The term “emitter electrode” is not limited to the definition of an electrode from which charge carriers are emitted to the transport medium. The term “emitter electrode” may also include an electrode from which more charge carriers are emitted to the transport medium relative to another electrode (e.g., the collector electrode) as some charge carriers may be generated from by transport medium. Similarly, the term “collector electrode” is not strictly limited to an electrode from which charge carriers are collected from the transport medium. The term “collector electrode” may also include an electrode from which more charge carriers are collected from the transport medium relative to another electrode (e.g., the emitter electrode) as some charge carriers may be generated by the transport medium.

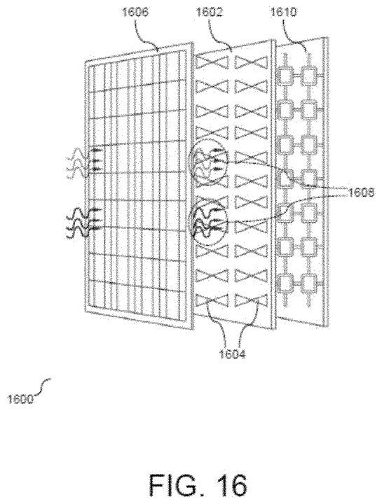

FIG. 17A shows a schematic representation of an architecture for an energy conversion device (1705). The energy conversion device (1705) includes at least a series of alternating electrodes separated by a transport medium (1730). The series of alternating electrodes separated by a transport medium (1730) may be organized into power-generating cells. The energy conversion device (1705) includes at least one cell (1750). Each cell (1750) includes at least two electrodes and a transport medium (1730). The two electrodes may comprise an emitter electrode (1720) and a collector electrode (1740). The emitter electrode (1720) and the collector electrode (1740) may be elongated and non-orthogonal to one other. The transport medium (1730) may be interposed between the at least two elongated electrodes such that the two elongated electrodes do not come into direct contact with each other between the two ends of the transport medium (1730).

The cell (1750) harvests kinetic energy to produce electric energy. For example, a difference in work function between the two electrodes results in a charge carrier transport between the emitter electrode (1720) and the collector electrode (1740). Higher temperatures may increase the rate of energy conversion to electrical energy. For instance, a high emitter electrode temperature raises electron energy, enabling more charge carriers to transport across the transport medium (1730). In some embodiments, the output of the energy conversion device (1705) is a large voltage difference between the emitter electrode (1720) and the collector electrode (1740) that is capable of producing a current ranging from picoAmps to milliAmps per square centimeter. In some embodiments, the output of the energy conversion device (1705) is a current flowing from the emitter electrode (1720) to the collector electrode (1740) with a modest voltage difference. In some embodiments, the output of the energy conversion device (1705) is a current flowing from the collector electrode (1740) to the emitter electrode (1720).

The cell (1750) may be stacked sequentially to create a pattern of cells across the energy conversion device (1705). The pattern of cells may include some collector electrodes structurally integrated into two cells. For example, a collector electrode (1740) may be a collector electrode for two or more adjacent power-generating cells. More specifically, the collector electrode (1740) may share a surface with each of the adjacent power-generating cells. This results in the collector electrode (1740) being shared between at least two cells. Additionally, the collector electrode (1740) may have opposing planar sides where each planar side interfaces with a different power-generating cell. In this manner, the stacked architecture enables both sides of the electrodes to be used for emission/collection, which yields increased compactness.

The electrodes may be positioned in a juxtaposed, stacked configuration. The electrodes may include a plurality of collector electrodes that are juxtaposed with a corresponding plurality of emitter electrodes and positioned in a stacked relationship. The electrodes may be separated from one another via a transport medium (1730), the transport medium (1730) potentially comprising a variety of materials or a vacuum. Each transport medium (1730) may be sandwiched between an emitter electrode (1720) and a collector electrode (1740). The stack thus forms a vertical series of cells in which at least one collector electrode (1740) is stacked atop a corresponding emitter electrode (1720) with a transport medium (1730) therebetween. In some embodiments, each cell (1750) may have the same dimensions (e.g., length and width) as the other cells in the energy conversion device (1705). The pattern of cells may extend in a vertical direction or a horizontal direction.

Electrodes from each cell (1750) may be electrically connected to the corresponding electrodes in an adjacent cell with a conducting material, such as a wire, a via hole, a solder, and/or a surface contact. For example, an emitter electrode (1720) from a first cell is electrically connected with another emitter electrode of an adjacent cell through a surface contact. In another example, the collector electrode (1740) from a first cell is electrically connected with another collector electrode of the adjacent cell through a wire. The electrodes of the cells may be interconnected by wiring, via holes, soldering, and/or surface contacts.

Thus, the cell (1750) may be formed by (1) a collector electrode (1740) having a top surface and a bottom surface; (2) an emitter electrode (1720) having a top surface and a bottom surface; and (3) a transport medium (1730) separating or otherwise interposed between the collector electrode (1740) and the emitter electrode (1720). The architecture may include a series of vertically arranged energy conversion cells. Alternatively, and/or additionally, the architecture may include a series of horizontally arranged energy conversion cells.

The cells may be stacked in any direction and to any dimension to scale output power. For example, additional cells may be stacked to scale output power. The thickness of the stacked architecture may be proportional to the power output. The cells may be co-power generating layers that are electrically interconnected or otherwise coupled in any of a wide variety of combination of series or parallel connections to achieve a desired power output.

The energy conversion device (1705) may include a pair of opposed, transverse side regions with a corresponding lead positioned on each side region (a collector lead on one side region and an emitter lead on an opposite side region). The layout of the side regions and the corresponding leads may facilitate the interconnection of the electrodes of the energy conversion device (1705). For example, the leads may face the exposed sides of the electrodes to make a connection to the corresponding electrodes. In some embodiments, the energy conversion cells are stacked in a vertical orientation, or in a direction non-orthogonal to the electrode surfaces, each cell (1750) including at least one collector electrode (1740) stacked atop a corresponding emitter electrode (1720) with the transport medium (1730) positioned therebetween. With this layout, each of the electrodes is exposed at the sides and may be electrically coupled to the leads on each side region. In this regard, at least one collector lead (1760) is positioned on a first side region of the device such that at least one collector lead (1760) is coupled to a corresponding combination of collector electrode (1740). In this manner, each of the collector electrodes is directly coupled or otherwise exposed to a corresponding collector lead (1760).

In addition, at least one emitter lead (1765) is positioned on a second, opposite side region of the energy conversion device (1705). Thus, at least one emitter lead (1765) is directly coupled or otherwise exposed to a combination of emitter electrode (1720) and transport medium (1730).

An emitter lead (1765) and a collector lead (1760) electrically connect to the emitter electrode (1720) and the collector electrode (1740), respectively. The emitter lead (1765) and the collector lead (1760) may be connected to at least one electrically driven component. The emitter lead (1765) and the collector lead (1760) may also be connected to any number of other devices in any number of series or parallel configurations. The leads may be scaled to maximize power output and efficiency. The leads may be made out of any conductive material.

Each collector electrode (1740) and emitter electrode (1720) may extend laterally a planar element (such as a wafer) having a thickness as well as a top side and a bottom side. Each electrode may be formed of one or more layers of material. For example, two or more metals may be layered to form the collector electrode (1740). In another example, the emitter electrode (1720) may be multilayers of thin films. The configuration of the electrodes, as well as the relative positioning of the electrodes, may vary. For example, the electrodes do not necessarily have to be positioned in a stacked, vertical orientation. The electrodes may also have shapes other than a wafer. In an example implementation, the electrodes are positioned to extend radially outward, such as from a core or a center point. The collector electrodes, emitter electrodes, and transport medium (1730) may also be positioned in a concentric arrangement. In some embodiments, the layers comprising the electrode may include a continuous covering of atoms or nanoparticles across a surface. Alternatively, and/or additionally, the layers comprising the electrode may include atoms or nanoparticles dispersed across the surface with portions of the surface exposed.

Each emitter electrode (1720) and/or collector electrode (1740) may comprise a conductive material. In some embodiments, the emitter electrode (1720) and/or the collector electrode (1740) may comprise an alkali metal such as Li, K, Na, Rb, Cs, and/or the like. In some embodiments, the emitter electrode (1720) and/or the collector electrode (1740) comprise an alkali earth metal, such as Be, Mg, Ca, Sr, Ba, and/or the like. In some embodiments, the emitter electrode (1720) and/or the collector electrode (1740) comprise a transition metal, such as Ti, Ni, Cu, Pd, Ag, Hf, W, Jr, Pt, Re, W, Mo, Au, and/or the like. In some embodiments, the emitter electrode (1720) and/or the collector electrode (1740) comprise a post-transition metal, such as Al, Ga, In, Tl, Sn, Pb, and/or the like. In some embodiments, the emitter electrode (1720) and/or the collector electrode (1740) comprise a metalloid, such as B, Si, Ge, As, Te, and/or the like. In at least one non-limiting implementation, the surface of the emitter electrode (1720) comprises Ti, Ni, Cu, Pd, Ag, Hf, W, Jr, or Au, and the surface of the collector electrode (1740) comprises Re, Pt, W, or Mo. In another non-limiting implementation, the surface of the collector electrode (1740) comprises Ti, Ni, Cu, Pd, Ag, Hf, W, Jr, or Au, and the surface of the emitter electrode (1720) comprises Re, Pt, W, or Mo.

The emitter electrode (1720) and the collector electrode (1740) may comprise the same conducting material. The emitter electrode (1720) and the collector electrode (1740) comprising the same conducting material may have different work functions. For example, the emitter electrode (1720) may have a surface treatment resulting in a lower work function than the work function of the collector electrode (1740). Similarly, the collector electrode (1740) may have a surface treatment creating a higher work function in the collector electrode (1740) than the work function of the emitter electrode (1720).

In some embodiments, the emitter electrode (1720) and the collector electrode (1740) are made of different conducting materials. For example, the emitter electrode (1720) may comprise aluminum and the collector electrode (1740) may comprise platinum. The conducting materials may be selected to achieve a desired work function and energy barrier behavior. For example, the emitter electrode (1720) may comprise a conducting material having a work function less than the work function of the collector electrode material. The emitter electrode (1720) may have a lower work function and the collector electrode (1740) may have a higher work function. The charge carrier flow within the externally connected circuit is driven by this difference in work function between the emitter electrode (1720) and the collector electrode (1740), resulting in charge carrier flow between the emitter electrode (1720) and the collector electrode (1740). In some non-limiting implementations, the charge carriers may flow through the transport medium (1730) from the higher work function to the lower work function. Charge carriers may flow when the device is in a non-equilibrium state. The non-equilibrium state may be attained by a different work functions at the emitter electrode (1720) and the collector electrode (1740). The non-equilibrium state may also be attained by a discontinuous energy band within the transport layer. In some embodiments, the transport layer maintains its insulative properties while allowing leakage of charge carriers between the electrodes. In some embodiments, the transport layer is semi-conducting with a sufficient bandgap to prevent electrical shorting between the electrodes. In some embodiments, the non-equilibrium state may be induced by changing the features such as an energy barrier height relative to the fermi level, an energy barrier height relative to vacuum, an energy barrier slope, a density of traps within the energy barrier, a depth of the traps within the energy barrier, and an intermediate stage adjacent to the energy barrier. In some embodiments, the non-equilibrium state may be induced by unique interaction between the charge carriers and other energy modes, such as, but not limited to, phonons. In some embodiments, interactions associated with polarons or excitons may induce a non-equilibrium state. In some embodiments, differing dominant tunneling behavior such as through barrier tunneling or over barrier tunneling between the surface of the emitter electrode (1720) and the surface of the collector electrode (1740) may induce a non-equilibrium state.

The emitter electrode (1720) and/or the collector electrode (1740) may comprise a semi-conductive material. The semi-conductive material may be undoped or doped. The dopant applied to the semi-conductive material may be slightly more conductive than the semi-conductive material of the emitter electrode (1720) and the collector electrode (1740). In some embodiments, the dopant may be dispersed from the top surface of the electrode to the bottom surface of the electrode. Alternatively, and/or additionally, the dopant may be concentrated at regions near the surfaces of the collector electrode (1740) or the emitter electrode (1720). The semi-conductive material may be Si-based or Ga-based with aluminum, antimony, bismuth, gold, phosphorous, boron, and/or the like as potential dopant options.

The emitter electrode (1720) and/or the collector electrode (1740) may comprise a 2D material. The 2D material may include crystalline material with a single uniform layer of atoms or molecules. For example, the 2D material may be a uniform layer of graphene, Si2BN, borophene, black phosphorus, tungsten disulfide, and/or the like. The 2D material may be attached to a structural support. For example, the structural support may extend laterally alongside the emitter and/or the collector electrode to prevent atomic diffusion and migration. The thickness of the 2D material may be as thin as a single angstrom thick. The 2D material may be placed within the plane and extend outside of the plane. The 2D material may behave as a coating. In some embodiments, the 2D material may be coupled to a conductive material of the electrode. In some embodiments, the 2D material may include a continuous covering of atoms or nanoparticles across a surface. Alternatively, and/or additionally, the 2D material may include atoms or nanoparticles dispersed across the surface with portions of the surface exposed.

The emitter electrode (1720) and/or the collector electrode (1740) may comprise a heterostructural material. The heterostructural material (Van der Waals heterostructures) may layer 2D materials with the distinguishing feature of having covalent bonding in-plane and Van der Waals force/bonding out of plane, creating isotropic material properties. The heterostructural material may comprise a compound, such as WSe2, MoS2, MoTe2, h-BN, Re, Pt, W, Mo, and/or the like. In some embodiments, the emitter electrode (1720) comprises WSe2, MoS2, MoTe2, or h-BN and the collector electrode (1740) comprises oxidized or non-oxidized Re, Pt, W, or Mo. In some embodiments, the collector electrode (1740) comprises WSe2, MoS2, MoTe2, or h-BN and the emitter electrode (1720) comprises oxidized or non-oxidized Re, Pt, W, or Mo. In some embodiments, the layers of the heterostructural material may include a continuous covering of atoms or nanoparticles across a surface. Alternatively, and/or additionally, the layers of the heterostructural material may include atoms or nanoparticles dispersed across the surface with portions of the surface exposed.

Alternatively, and/or additionally, the emitter electrode (1720) and the collector electrode (1740) may comprise any other suitable conducting material or combination, such as a metal alloy, a compound, and/or a mixture. For example, the emitter electrode (1720) may comprise Indium Tin Oxide. Furthermore, the emitter electrode (1720) and the collector electrode (1740) may constitute different materials and may have different structures. For example, the emitter electrode (1720) may be a semiconductor and the collector electrode (1740) may be a metal. In another example, the emitter electrode (1720) may be a 2D material and the collector electrode (1740) may be a heterostructural material.

The thickness of the emitter electrode (1720) and collector electrode (1740) may measure between 0.1 nm and 100 μm in diameter. In some embodiments, the thickness of the emitter and the collector electrode is at or about 10 nm for density critical applications. The thickness of the electrodes may be reduced to increase the packaging density. In some embodiments, the collector electrode (1740) may have a thickness greater than the emitter electrode (1720). In some embodiments, the emitter electrode (1720) may have a thickness greater than the collector electrode (1740). In some embodiments, the emitter electrode (1720) and/or the collector electrode (1740) provide structural support for the stacked architecture. The emitter and collector electrodes may be fabricated using deposition techniques, such as PVD, CVD, spin-on coating, self-assembly, etching, lithography, and/or a similar manufacturing process.

FIG. 17B shows an energy-generating layer including an optional surface treatment, in accordance with some example embodiments. The work function of the surface of the emitter electrode and the collector electrode may be modified through a surface treatment. An emitter surface treatment (1722) may be added to a surface of the emitter electrode (1720) to modify the work function of the emitter electrode (1720). The collector electrode (1740) may also include a collector surface treatment (1738) configured to modify its work function, resulting in a desired work function differential between an emitter electrode (1720) and a collector electrode (1740).

The emitter surface treatment (1722) and the collector surface treatment (1738) may include surface features such as roughness, spikes, spheres, pins, pits, pillars, and/or the like. The surface features may be spaced from each other to adjust the work function of the emitter electrode (1720) and the collector electrode (1740). More surface features may be added to the surface of the emitter electrode (1720) and/or the collector electrode (1740) until the desired work function differential is achieved. The surface features may be created through deposition techniques, such as PVD, CVD, spin-on coating, self-assembly, etching, lithography, and/or a similar manufacturing process. The surface features may control the sensitivity of tunneling of charge carriers between the emitter electrode (1720) and the collector electrode (1740).

The emitter surface treatment (1722) and/or the collector surface treatment (1738) may include a chemical application. The chemical application may lower the work function until the desired work function differential is achieved between the emitter electrode (1720) and the collector electrode (1740). For example, the emitter surface treatment (1722) may be treated with Cs2O to lower its work function. The chemical may comprise Cs2O, CsF, CH3OH, CsCO3, chlorine compounds, fluorine compounds, cesium compounds, non-stoichiometric cesium oxides, and/or cesium fluorides. The collector surface treatment (1738) may aim to increase the work function, and include chemicals such as NO2-PyT (PyT standing for pyrene-tetraone), Br-PyT, Cl-ITO, Re, Pt, W, Mo and/or the like. In some embodiments, the collector surface treatment (1738) may comprise NO2-PyT (PyT standing for pyrene-tetraone), Br-PyT, Cl-ITO, Re, Pt, W, Mo and/or the like

The chemical application may include a uniform layer of atoms or compounds along the length of the emitter electrode (1720) and/or the collector electrode (1740). In some embodiments, the chemical treatment may include a continuous covering of atoms or nanoparticles across a surface. Alternatively, and/or additionally, the chemical treatment may include atoms or nanoparticles dispersed across the surface with portions of the surface exposed. In some embodiments, the emitter surface treatment (1722) and/or the collector surface treatment (1738) may be modified with a continuous or non-continuous film containing an impurity that reacts with the electrode. In a non-limiting implementation, the impurity may include Cs2O, CsF, CH3OH, CsCO3, chlorine compounds, fluorine compounds, cesium compounds, non-stoichiometric cesium oxides, and/or cesium fluorides.

The dopant may react with the metal of the electrode to vary the electrical properties (e.g., capacitance, the inductance, the resistance, and the conductivity) of the conductive metal. The dopants may vary in carrier concentration and mobility between the emitter electrode (1720) and the collector electrode (1740). For example, the dopant may have a greater carrier concentration at the emitter electrode (1720) in comparison to the collector electrode (1740). In at least one embodiment, the collector surface treatment (1738) includes a chemical treatment disposed uniformly along the outside surface along at least one length of the collector electrode (1740). Alternatively, and/or additionally, the chemical treatment may be evenly spread across the surface of the collector and/or emitter electrode but only covers a fraction of the total surface area.

Alternatively, and/or additionally, the chemical treatment may be applied in an alternating pattern along the surface of the collector electrode (1740) and/or the emitter electrode (1720). The thickness of the application of the chemical treatment varies between 0.1 nanometers to 100 nanometers. The emitter surface treatment (1722) may be applied to one or both sides of the emitter electrode (1720). The collector surface treatment (1738) may be applied to one or both sides of the collector electrode (1740). The chemical treatment may be applied using deposition techniques, such as PVD, CVD, spin-on coating, self-assembly, etching, lithography, and/or a similar manufacturing process.

The emitter surface treatment (1722) and/or the collector surface treatment (1738) may include a modified layer. The modified layer may include a layer of Cs, Fr, K, Cl, F, and/or the like. In some embodiments, the modified layer may include a continuous covering of atoms or nanoparticles across a surface. Alternatively, and/or additionally, the modified layer may include atoms or nanoparticles dispersed across the surface with portions of the surface exposed.

In some embodiment, the emitter surface treatment (1722) and the collector surface treatment (1738) have a larger planar dimension than the transport medium (1730) in at least one direction to achieve electrical interconnection with the emitter lead (1765) or the collector lead (1760). In some embodiments, the emitter surface treatment (1722) and/or the collector surface treatment (1738) extend up to or beyond the planar dimension of the transport medium (1730). In some embodiments, the transport medium (1730) material and the adjacent emitter surface treatment (1722) or adjacent collector surface treatment (1738) are flush along a vertical side of the energy conversion device (1705). In some implementations, the emitter electrode (1720) and the collector electrode (1740) have a larger planar dimension than the transport medium (1730) in at least one direction to achieve electrical interconnection with the emitter lead (1765) or the collector lead (1760). In some embodiments, the emitter electrodes and the collector electrodes extend up to or beyond the planar dimension of the transport medium (1730). In some embodiments, the transport medium (1730) material and the adjacent collector electrode (1740) or emitter electrode (1720) are flush along a vertical side of the energy conversion device (1705).

Turning again to FIG. 17A, charge carriers may flow between the emitter electrode (1720) and the collector electrode (1740). The difference in the work function of the emitter electrode (1720) and the work function of the collector electrode (1740) may result in a charge carrier flow between the two electrodes. In some embodiments, the emitter electrode (1720) has a lower work function and the collector electrode (1740) has a higher work function. An energy barrier configuration between the two electrodes may reduce the flow of charge carriers between the collector electrode (1740) and the emitter electrode (1720). In some non-limiting implementations, the energy barrier configuration between the two electrodes may reduce charge carrier transport from the collector electrode (1740) to the emitter electrode (1720). The transport medium (1730) may electrically isolate the emitter electrode (1720) and the collector electrode (1740) from each other while allowing for charge carrier transport therebetween.

With respect to the transport medium (1730), the size and configuration of the transport medium (1730) may vary. The transport medium (1730) may comprise a vacuum having a thickness of about 0.1 nm to 10.0 μm. The transport medium (1730) may also include a gas or a vapor with a corresponding thickness of about 0.1 nm to 10.0 μm where the vapor comprises, for example Cs, metal ions, SF6, C4F8, Ar, and/or the like. The thickness of the transport medium (1730) may be 200 nm or less. In one non-limiting implementation, the thickness of the transport medium (1730) may be between 1 nm to 10 μm. The transport medium (1730) may be interposed between the at least two elongated electrodes such that the two elongated electrodes do not come into direct contact with each other.

The transport medium (1730) may also include a solid material including for example: a dielectric insulator such as Al2O3, HfO2, Ta2O5, Nb2O5, SiO2; a 2D material, such as graphene, Si2BN, borophene; a heterostructure materials such as WSe2, MoS2, MoTe2, h-BN, Re, Pt, W, Mo; a semiconductor such as doped/undoped, Si-based, Ga-based material; and/or an organic compound such as one or more polymers, self-assembled monolayers, and/or alkanethiols. The transport medium (1730) may be fabricated using deposition techniques, such as PVD, CVD, spin-on coating, self-assembly, etching, lithography, and/or a similar manufacturing process. The transport medium (1730) may be a crystalline, amorphous, or polycrystalline based on the deposition technique. In some embodiments, the transport medium (1730) may comprise a self-assembled monolayer. In some implementations, the transport medium (1730) may comprise various combinations of metals and insulators layered together. For example, the transport medium (1730) may include a metal-insulator-metal layer that may be combined with other layers. In another example, the transport medium (1730) may include a metal-insulator-metal-insulator-metal that may be combined with other layers. In another example, the transport medium (1730) may include a metal-insulator-insulator-metal layer that may be combined with other layers. In some embodiments, the layers of the transport medium (1730) may include a continuous covering of atoms or nanoparticles across a surface. Alternatively, and/or additionally, the layer of the transport medium (1730) may include atoms or nanoparticles dispersed across the surface with portions of the surface exposed.

Quantum tunneling, such as direct tunneling, Fowler-Nordheim tunneling, trap-assisted tunneling, Poole-Frenkel emission, Schottky effect, and/or thermionic emission may transport charge carriers across the transport medium (1730). Transportation of charge carriers across the transport medium may be accomplished by manipulating the characteristics of the energy barrier(s) to achieve a non-equilibrium state. The non-equilibrium state may be achieved by adjusting the work functions of the electrodes and the various features of the energy barrier, such as an energy barrier height relative to the fermi level, an energy barrier height relative to vacuum, an energy barrier slope, a density of traps within the energy barrier, a depth of the traps within the energy barrier, and an intermediate stage adjacent to the energy barrier.

In some embodiments, the disclosed architecture allows for a compact structure and improves efficiency that draws heat from the sides of the device to be absorbed by the emitter and collector leads. The emitter and collector leads, in turn evenly disperse the heat to each of the electrode layers. The device may also include one or more structural features, such as pillars, that enhance or otherwise modify the structural integrity and electrical interconnectivity of the device.

Additional insulating material may be added to maximize the energy conversion efficiency of the device. To maximize efficiency, the emitter electrode (1720) may be insulated from colder external elements and the collector electrode (1740) may be insulated from warmer external elements. Further, the emitter electrode (1720) may be isolated from components electrically connected to the collector electrode (1740). Additionally, the collector electrode (1740) may be electrically isolated from components electrically connected to the emitter electrode (1720). To solve this problem, an insulating wall may cover the stacked cell architecture.

To further maximize energy conversion efficiency, the energy conversion device (1705) may include a plurality of conductive leads surrounding the energy conversion device (1705) to avoid a temperature gradient across the electrodes. For example, two leads may be placed at opposing ends of the emitter electrodes in one direction and two additional leads may be placed at opposing ends of the collector electrodes in a different direction. The two sets of opposing leads may be sources of thermal energy for the respective electrodes. In this manner, the emitter electrodes and the collector electrodes maintain a consistent temperature gradient from end to end.

The energy conversion device (1705) may be encased in a common outer shell to provide an embeddable integrated electrical package. The device may be encased in a common outer shell with an electrically driven component in a common outer shell to provide the embeddable integrated electrical package. Additionally, the energy conversion device (1705) may be stacked using semiconductor, CMOS techniques, and/or MEMS packaging techniques including wafer bonding, interposers, wafer thinning, and other processes. These packaging techniques may enhance performance and reduced manufacturing costs.

The thickness of the stacked architecture may be determined by the number of cells or electrical power generating layers. The stacked architecture may be scaled up or down depending on the power demands of the electrically driven component. The stacked architecture may be scaled up or down for a variety of applications.

An external thermal bias may enhance the conversion efficiency from thermal energy to electricity. For example, the device may harvest energy from an engine or human skin to generate electricity. Additionally, an external thermal bias may enhance the conversion efficiency from thermal energy to electricity with increased absolute temperature. The packaging may be designed to conduct thermal energy through electrodes, wires, fins, and/or the like. The packaging may be configured to be attached to buildings, structures, and/or vehicles to capture thermal energy. The packaging may be scaled up or down for a variety of applications.

The energy conversion device (1705) may require an external potential difference bias to activate the energy conversion device (1705). For example, the current flow may be minimal between the emitter electrode (1720) and the collector electrode (1740). An external potential difference bias may initiate the current flow. The external voltage bias may be applied between the emitter electrode (1720) and the collector electrode (1740). Alternatively, and/or additionally, the external voltage bias may be applied between the emitter lead (1765) and the collector lead (1760).

In use, the emitter electrodes may be exposed to heat to promote charge carrier transport. In some embodiments, the collector electrodes may receive the transferred charge carriers from the emitter electrodes. As mentioned, the gap between the electrodes may be a vacuum but may also be filled with a solid, liquid, or gas. The kinetic energy may be supplied by any of a variety of sources, including but not limited to thermal, chemical, solar, vibrational, or nuclear sources. Thus, energy conversion device (1705) may be used to power any of a variety of devices, including but not limited to, waste heat recovery, energy scavenging, co-power generation, and direct energy sources.

The energy conversion device (1705) may be activated when connected to an electrical load. An electrically driven component may be provided with a conductive interface (e.g., pads, leads, wires). The electrically driven component may be powered when connected to the energy conversion device (1705).

The energy conversion device (1705) may be configured to convert energy for stationary power, electric vehicles, urban air mobility, and devices of the IoT. The energy conversion device (1705) may be attached to a building structure or a vehicle structure to harvest energy.

FIG. 17C shows another energy-generating layer including a low work function surface and a high work function surface, in accordance with some example embodiments. An electrode (1718) may include at least two opposing surfaces. The two opposing surfaces may be approximately parallel to one another. The first opposing surface may contact a low work function surface (1726). The second surface may contact a high work function surface (1728). Alternatively, the first opposing surface may contact a high work function surface (1728) and the second surface may contact a low work function surface (1726). In some embodiments, the first opposing surface contacts the transport medium (1730) while the second opposing surface of the same electrode contacts a high/low work function surface. In some embodiments, the second opposing surface contacts the transport medium (1730) while the first opposing surface of the same electrode contacts a high work function surface (1728) or a low work function surface (1726).

The high work function surface (1728) and the low work function surface (1726) may be a material disposed on the electrode (1718). For instance, the high work function surface (1728) and the low work function surface (1726) may comprise the same material. The difference in work function between the high work function surface (1728) and the low work function surface (1726) may be achieved by varying the thickness of the material. For example, the high work function surface (1728) may be thinner than the low work function surface (1726). In some embodiments, the high work function surface (1728) and the low work function surface (1726) may comprise different materials. For example, the high work function surface (1728) may be an aluminum layer disposed on the upper side of the electrode (1718) and the low work function surface (1726) may be a platinum layer disposed on the lower side of the electrode (1718). The materials may be selected to achieve a desired work function and energy barrier behavior.

The high work function surface (1728) and/or the low work function surface (1726) may comprise a semi-conductive material. The semi-conductive material may be undoped or doped. The dopant may be slightly more conductive than the semi-conductive material of the emitter electrode (1720) and the collector electrode (1740). Alternatively, and/or additionally, the semi-conductive material may be applied in an alternating pattern across the collector electrode (1740) or the emitter electrode (1720). The semi-conductive material may be Si-based or Ga-based with aluminum, antimony, bismuth, gold, phosphorous, boron, and/or as potential dopant options.

The high work function surface (1728) and/or the low work function surface (1726) may comprise a 2D material. The 2D material may include a crystalline material including a single uniform layer of atoms or molecules. For example, the 2D material may be a uniform layer of graphene, Si2BN, borophene, and/or the like. The high work function surface (1728) and/or the low work function surface (1726) may comprise a heterostructural material. The heterostructural material may comprise a compound, such as WSe2, MoS2, MoTe2, h-BN, Re, Pt, W, Mo, and/or the like. In some embodiments, the high work function surface (1728) comprises WSe2, MoS2, MoTe2, or h-BN and the low work function surface (1726) comprises oxidized or nonoxidized Re, Pt, W, or Mo. In some embodiments, the low work function surface (1726) comprises WSe2, MoS2, MoTe2, or h-BN and the high work function surface (1728) comprises oxidized or nonoxidized Re, Pt, W, or Mo. In some embodiments, the layer of the high work function surface (1728) and/or the low work function surface (1726) may include a continuous covering of atoms or nanoparticles across a surface. Alternatively, and/or additionally, the layer of the high work function surface (1728) and/or the low work function surface (1726) may include atoms or nanoparticles dispersed across the surface with portions of the surface exposed.

Alternatively, and/or additionally, the high work function surface (1728) and the low work function surface (1726) may comprise suitable conducting material or a combination thereof, such as a metal alloy, a compound, and/or a mixture. For example, the high work function surface (1728) may comprise indium tin oxide. Furthermore, the high work function surface (1728) and the low work function surface (1726) may constitute different materials and may have different structures. For example, the high work function surface (1728) may be a semiconductor and the low work function surface (1726) may be a metal. In another example, the high work function surface (1728) may be a 2D material and the low work function surface (1726) may be a heterostructural material. In another non-limiting implementation, the high work function surface (1728) and the low work function surface (1726) may comprise single and multiwalled carbon nanotubes, graphene flakes, graphitic flakes, diamond clusters, graphitic particles, carbon fibers, carbon ring structures, phosphorus-doped diamond, cesiated diamond, carbon nitride, hydrogenated diamond, nitrogen containing hydrogenated diamond, and boron carbon nitride.

The high work function surface (1728) and the low work function surface (1726) may comprise a treatment applied to the electrode. The surface treatment may include surface features such as roughness, spikes, spheres, pins, pits, pillars, and/or the like. The surface features may be spaced from each other to adjust the work function. The surface treatments may comprise a thin film comprising polycrystalline grains. In at least one implementation, the polycrystalline grains may have a thickness with a quadratic mean ranging between 0.5 to 5 nm. The surface features may be created through deposition techniques, such as PVD, CVD, spin-on coating, self-assembly, etching, lithography, and/or a similar manufacturing process. The surface features may control the sensitivity of tunneling of charge carriers between the electrodes.

The surface treatment of the high work function surface (1728) and/or the low work function surface (1726) may include a chemical application. The chemical may lower the work function until the desired work function differential is achieved. For example, the low work function surface (1726) may be treated with Cs2O to lower its work function. The chemical may comprise Cs2O, CsF, CH3OH, CsCO3, chlorine compounds, fluorine compounds, cesium compounds, non-stoichiometric cesium oxides, and/or cesium fluorides. The electrode surface treatment may aim to increase the work function, and include chemicals such as NO2-PyT (PyT standing for pyrene-tetraone), Br-PyT, Cl-ITO, and/or the like. The chemical may include a uniform layer of atoms or compounds along the length of the high work function surface (1728) and/or the low work function surface (1726). In some embodiments, the high work function surface (1728) and/or the low work function surface (1726) may be doped with an impurity, such as Cs2O, CsF, CH3OH, CsCO3, chlorine compounds, fluorine compounds, cesium compounds, non-stoichiometric cesium oxides, and/or cesium fluorides. The dopant may react with the metal of the electrode to vary the electrical properties (e.g., capacitance, the inductance, the resistance, and the conductivity) of the conductive metal. The dopants may vary in carrier concentration and mobility between the high work function surface (1728) and the low work function surface (1726). For example, the dopant may have a greater carrier concentration at the high work function surface (1728) in comparison to the low work function surface (1726). The chemical treatment may be evenly spread across the surface of the high work function surface (1728) or the low work function surface (1726) but only covers a fraction of the total surface area. Alternatively, and/or additionally, the chemical treatment may be applied in an alternating pattern along surface of the high work function surface (1728) or the low work function surface (1726). The thickness of the application of the chemical treatment varies between 0.1 nanometers to 100 nanometers.

The high work function surface (1728) and/or the low work function surface (1726) is between 1 nm and 1 μm in thickness. In some embodiments, the high work function surface (1728) may have a thickness greater than the low work function surface (1726). In some embodiments, the low work function surface (1726) may have a thickness greater than the high work function surface (1728). For example, the high work function surface (1728) may be hundreds of nanometers thick while the low work function surface (1726) may be a single angstrom thick. The work function across the high work function surface (1728) may differ based on a varying thickness, composition, and treatment applied. Additionally, and/or alternatively, the work function across the low work function surface (1726) may differ based on a varying thickness, composition, and treatment applied. The high work function surface (1728) and/or the low work function surface (1726) may be fabricated using deposition techniques, such as PVD, CVD, spin-on coating, self-assembly, etching, lithography, and/or a similar manufacturing process. Multiple high work function surfaces may be electrically connected to each other in any number of series or parallel configurations. Multiple low work function surfaces may be electrically connected to each other in any number of series or parallel configurations.

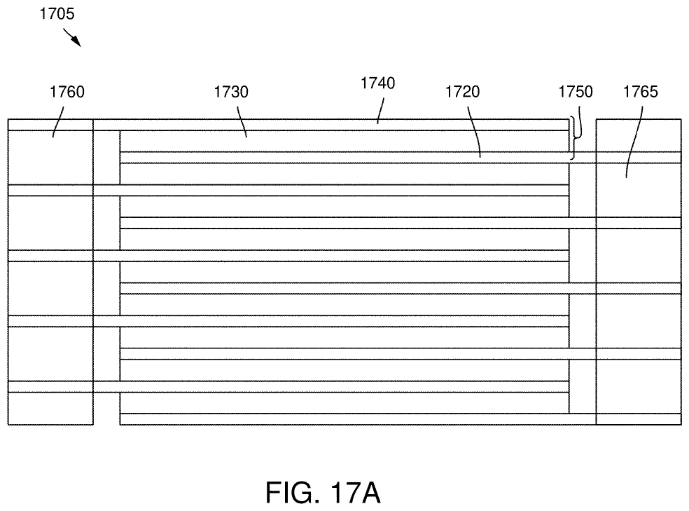

FIG. 18A shows another energy-generating layer comprising a transport medium including a nanoparticle solution, in accordance with some example embodiments. The nanoparticle solution (1810) has dielectric properties. The nanoparticle solution (1810) may comprise a dielectric liquid including, for example, silicone oil, purified water, hexane, tetradecane, toluene, hydrocarbons, and the like. The nanoparticle solution (1810) may include an electrolytic solution. The nanoparticle solution (1810) may include a fluid with suspended nanoparticles. The transport medium (1730) may comprise a nanoparticle solution (1810) interposed between the emitter electrode (1720) and the collector electrode (1740). The nanoparticle solution (1810) may have a thickness of 0.1 nm to 10 μm. The dielectric properties of the nanoparticle solution (1810) may enable quantum tunneling of charge carriers between the emitter electrode (1720) and the collector electrode (1740).

In some embodiments, the nanoparticle solution (1810) is encapsulated between the emitter electrode (1720) and the collector electrode (1740). For example, the nanoparticle solution (1810) is sealed between an emitter electrode (1720) made of platinum and a collector electrode (1740) made of aluminum. The emitter electrode (1720) and the collector electrode (1740) may require standoffs (1820) at the ends of the emitter electrode (1720) and the collector electrode (1740). Additionally, the standoffs (1820) may be dispersed throughout the transport medium (1730) to maintain structural support. A sealant (1830) may be placed adjacent to the standoffs to retain the nanoparticle solution (1810). For example, the sealant (1830) may be disposed at the sides of the transport medium (1730) to retain the nanoparticle solution (1810). Additionally, the standoffs (1820) may function as a sealant or including a seal layer. The transport medium (1730) comprising the fluid may include one or more solid structures, such as a pillar, placed between the surfaces of the emitter electrode (1720) and the collector electrode (1740).

FIG. 18B shows a schematic representation of an architecture of an energy conversion device including the nanoparticle solution, in accordance with some example embodiments. As shown, the power-generating cells may encapsulate the nanoparticle solution (1810). Multiple liquid chambers may be stacked between the emitter electrodes and the collector electrodes. The standoffs (1820) and the sealant (1830) may extend continuously between the cells. For example, the sealant (1830) may extend continuously in a vertical direction to retain the nanoparticle solution (1810). In some embodiments, the standoffs (1820) and the sealant (1830) may extend continuously between the cells and are only interrupted by the emitter electrode (1720) and the collector electrode. The standoffs (1820) and the sealant (1830) may extend between the emitter and collector electrodes of each cell (1750) of the multi-stacked cells. A supporting wall may extend between the multiple liquid chambers to support the stacked architecture. For example, the supporting wall may extend continuously in a vertical direction between the cells to support the stacked multiple cells. The supporting wall may be straight for ensuring the cells extend in a uniform direction. The sealant (1830) may be placed adjacent to the wall to retain the liquid within the chambers. The emitter lead (1765) and the collector lead (1760) may face the outside surface of the sealant (1830). Alternatively, and/or additionally, the emitter lead (1765) and the collector lead (1760) may face the outside surface of the sealant (1830).

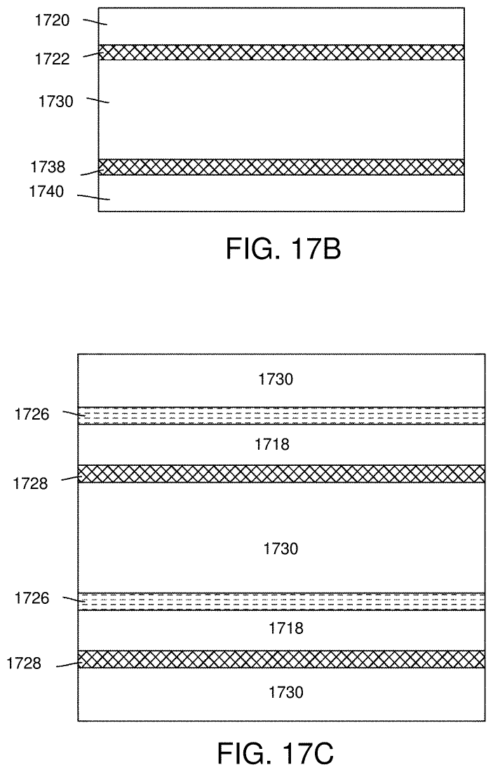

FIG. 19A shows nanoparticles in accordance with some example embodiments. The nanoparticle solution (1810) may include nanoparticles (1910). The nanoparticles (1910) may comprise conductive materials, such as gold, silver, copper, aluminum, titanium, nickel, platinum, lanthanum hexaboride, and/or the like. For example, gold nanoparticles may be immersed in nanoparticle solution (1810) comprising tetradecane. In a non-limiting implementation, the nanoparticles may comprise Au, Ag, Pt, Ti, Pt, La, GaN, GaP, InP, InAs, ZnO, ZnS, CdS, CdSe, CdTe, SiO2, Al2O3, HfO2, TiO2, Mn3O4, single and multiwalled carbon nanotubes, graphene flakes, graphitic flakes, diamond clusters, graphitic particles, carbon fibers, and carbon ring structures. The nanoparticles (1910) may be more conductive than the nanoparticle solution (1810). Some nanoparticles may have materials dissimilar from other nanoparticles. The nanoparticles (1910) may have a work function less than the work function of the emitter electrode (1720) and greater than the work function of a collector electrode (1740). Additionally, the nanoparticles (1910) may have a work function less than the work function of the nanoparticle solution (1810). The nanoparticles (1910) may comprise a conductive material such that the nanoparticles (1910) have a work function lower than the collector electrode (1740). Some nanoparticles may have a higher work function relative to other nanoparticles. The nanoparticles (1910) may be core-shell nanoparticles for enhancing the charge carrier transport between the emitter electrode (1720) and the collector electrode (1740). The core-shell nanoparticles may include a film (1920) having insulative properties. The film (1920) may comprise an electrosprayed dipole that encompasses the nanoparticles (1910). The film (1920) may be a monolayer film having a thickness of fewer than ten nanometers. Additionally, and/or alternatively, the film (1920) may include various layers having a thickness of less than 10 nm. The film (1920) may have a thickness of less than 10 nm. In some embodiments, the film (1920) has a thickness of 0.5 nm. In some embodiments, the film (1920) has a thickness of either 0.25 nm or 0.75 nm. The nanoparticles may enable trap-assisted tunneling.

Some nanoparticles may have a larger particle size than other nanoparticles. For example, a nanoparticle may have a diameter of 2 nm and another nanoparticle may have a diameter of 10 nm in the nanoparticle solution (1810). In another embodiment, the nanoparticles have a diameter of 3-4 nm. In some embodiments, the nanoparticles have a diameter of 4-5 nm with film (1920). The nanoparticles (1910) may range in size from 1 to 100 nanometers in diameter. In some embodiments, a self-assembled monolayer may cover the nanoparticles (1910). The thin film may comprise an electrosprayed dipole. In some embodiments, nanoparticles having a larger diameter relative to other nanoparticles in the nanoparticle solution (1810) may be positioned closer to the low work function surface (1726). Alternatively, and/or additionally, nanoparticles having a smaller diameter relative to other nanoparticles in the nanoparticle solution (1810) may be positioned closer to the low work function surface (1726). In some embodiments, the layer of nanoparticles may include a continuous covering of atoms or nanoparticles across a surface. Alternatively, and/or additionally, the layer of nanoparticles may include atoms or nanoparticles dispersed across the surface with portions of the surface exposed.

In some embodiments, the nanoparticles (1910) may be integrated into a solid material rather than a solution. For example, gold nanoparticles may be integrated into alumina or a polymer. The thickness of the solid may range from 0.1 nm to 10 μm. The nanoparticles (1910) may be distributed evenly throughout the solid material. The nanoparticles (1910) may be distributed closer to one work surface than the other. For example, the nanoparticles (1910) may be distributed closer to the low work function surface (1726) than the high work function surface (1728). In another example, the nanoparticles (1910) may be distributed closer to the high work function surface (1728) than the low work function surface (1726). In some embodiments, nanoparticles having a larger diameter relative to other nanoparticles in the same solid material may be positioned closer to the low work function surface (1726). Alternatively, and/or additionally, nanoparticles having a smaller diameter relative to other nanoparticles in the same solid material may be positioned closer to the low work function surface (1726). In some embodiments, the transport medium (1730) may be treated with a dip coating process or a Langmuir Blodgett coating process to produce core-shell nanoparticles.

FIG. 19B shows nanoparticles in a transport medium interposed between the emitter and the collector in accordance with some example embodiments. The transport medium (1730) may also comprise a vacuum, a gas or vapor, or a fluid, formed by, for example, chemical etching.

The nanoparticles (1910) may have a work function lower than the work function of the high work function surface (1728). The nanoparticles (1910) may have a work function lower than the work function of the high work function surface (1728) and higher than the work function of the low work function surface (1726). In some embodiments, the nanoparticles (1910) may have a work function lower than work function of the collector electrode (1740). In some embodiments, the nanoparticles (1910) may have a work function lower than the work function of the collector electrode (1740) and higher than the work function of the emitter electrode (1720).

In some implementations, the nanoparticles (1910) may have a work function higher than the work function of the low work function surface (1726). The nanoparticles (1910) may have a work function higher than the low work function surface (1726) and lower than the work function of the high work function surface (1728). In some embodiments, the nanoparticles (1910) may have a work function higher than the work function of the emitter electrode (1720). In some embodiments, the nanoparticles (1910) may have a work function higher than the work function of the emitter electrode (1720) and lower than the work function of the collector electrode (1740).

In some embodiment, the nanoparticles and/or the traps may reach equilibrium between the emitter electrode (1720) and the collector electrode (1740) after power has been generated over a period of time. The traps may be the nanoparticles or defects included in the transport medium (1730). If the current drops, then the emitter electrodes and the collector electrodes may be disconnected, and then reconnected. Optionally, the emitter electrodes and the collector electrodes may be grounded between the disconnecting and reconnecting the electrodes. This enables the energy conversion capacity of the energy conversion device (1705) to be rapidly recovered. After reconnecting the electrodes by the electrical switch, the currents described earlier will be reestablished and these charge carriers will charge the nanoparticles and/or the traps across the transport medium (1730).

A switch may be configured to intermittently connect the emitter electrode (1720) and the collector electrode (1740). The switch may be configured to disconnect, ground, and rapidly reconnect the emitter electrode (1720) and the collector electrode (1740). The switch may be configured to activate based on a current from the emitter electrode (1720) to the collector electrode (1740) satisfying a threshold.

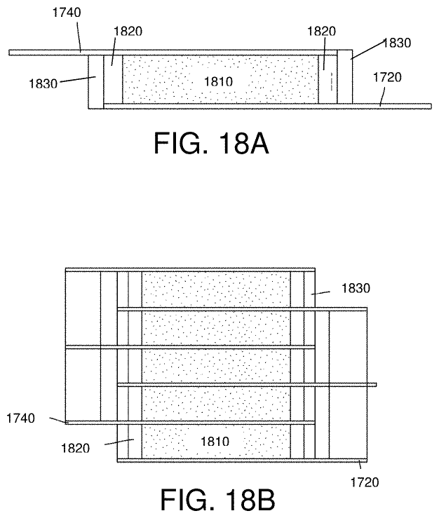

FIG. 20 shows an atomic lattice including a trap for trap-assisted charge carrier transport, in accordance with some example embodiments. The atomic layer (2000) may represent the transport medium (1730) over which a charge carrier must pass between the emitter electrode (1720) and the collector electrode (1740). The atomic layer (2000) may comprise a crystalline structure having a monoatomic solid layout. The crystalline structure features adjoining atoms evenly distributed across a planar area in their natural state. In its natural state, the atomic layer (2000) has a balance of bonds between the atoms. Traps may be introduced that disrupt the spacing of the atoms in the atomic layer (2000). Traps may be embodied by a defect in the atomic layer or as a nanoparticle in the atomic layer. The traps may include a natural defect in the atomic layer (2000) or a metal contaminant introduced into the atomic layer (2000). For example, the introduction of a Boron atom may disrupt the spacing in the crystalline structure. The traps may be electron sites that promote electron or other charge carrier transportation across the atomic layer (2000). Optionally, the atomic layer (2000) need not have a crystalline structure. The traps may be formed in other structures, such as a gas or liquid, enabling the atomic bonding to freely associate with adjacent atomic structures. The atomic layer (2000) may comprise an atomic lattice.

A trap may include an imbalance of bonding between adjacent atoms. This imbalance attracts or repels charge carriers facilitating transport across the transport medium. Examples of traps include a vacancy trap (2010), an interstitial trap (2020), a substitutional larger atom (2030), and a substitutional smaller atom (2040). The vacancy trap (2010) may be characterized by an imbalanced bond missing an electron. For example, an imbalanced bond due to a vacancy of an oxygen atom attracts electrons. The vacancy trap (2010) is missing an electron that provides a conductive site as the electron crosses the transport medium (1730). The interstitial trap (2020) may be characterized by an imbalanced bond with an extra bond. For example, an imbalanced bond due to an extra oxygen atom repels electrons. A substitutional larger atom (2030) having a greater atomic mass than the adjacent atoms may also disrupt the continuity of the balanced bonds in the atomic layer (2000). For example, a substitutional larger atom (2030), such as In, may be placed in the atomic layer (2000), resulting in stronger bonds between the In atom and the immediately surrounding atoms. These stronger bonds promote electron mobility by repelling electrons to available electron sites. The substitutional smaller atom (2040) having a smaller atomic mass than the adjacent atoms may also disrupt the continuity of the balanced bonds in the atomic layer (2000). For example, the substitutional smaller atom (2040), such as B, may be placed in the atomic layer (2000), resulting in weaker bonds between the B atom and the immediately surrounding atoms. These stronger bonds promote electron mobility by repelling electrons to available electron sites. Electron mobility may be guided across the transport medium (1730) with proximate vacancies and interstitial pairs. A proximate vacancy and interstitial pair may be considered a Frenkel Pair (2050).

The nanoparticles may encourage quantum tunneling across the transport medium (1730). The term “quantum tunneling” is not limited to the definition of a charge carrier passing from one end of the transport medium (1730) to the opposite end of the transport medium (1730). The term “quantum tunneling” may also include direct tunneling, trap-assisted tunneling, phonon-assisted tunneling, Fowler-Nordheim tunneling, and leakage tunneling. For example, quantum tunneling may occur between charge carrier traps in the transport medium (1730) without traversing the entire transport medium (1730) in a single movement. Charge carrier traps in solid transport medium may enable trap-assisted tunneling or Poole-Frenkel emission. The transport medium (1730), including a solid material, may include traps. The traps may be created by defects or nanoparticles. The traps enhance electron transport across the transport medium (1730). For example, the traps may be missing oxygen atoms that provide locations for the electrons to cross the transport medium (1730). The missing oxygen atoms may act as extra sites that attract electrons. The nanoparticle solution (1810) may use quantum tunneling to transport charge carriers across the transport medium (1730).

The atomic layer (2000) may be a gas, vapor, solid, solution, a solution with nanoparticles, or a solid with nanoparticles. The atomic layer (2000) may have insulating or semiconductor properties, including low electrical conductivity and/or low thermal conductivity. The atomic layer (2000) may comprise any material for the transport medium (1730). The trap may comprise the nanoparticles embedded in a solid material or nanoparticles situated in a fluid. The traps may have strong or excessive electron bonds in comparison to the electron bonds in the atomic layer (2000). The traps may have weak or vacant electron bonds in comparison to the electron bonds in the atomic layer (2000). The traps may comprise a discrete site of a bonding imperfection in the atomic layer (2000). The traps enhance electron transport across the transport medium (1730). In some embodiments, traps may be formed at defects within the insulator or semiconductor crystalline structure of the atomic layer (2000).

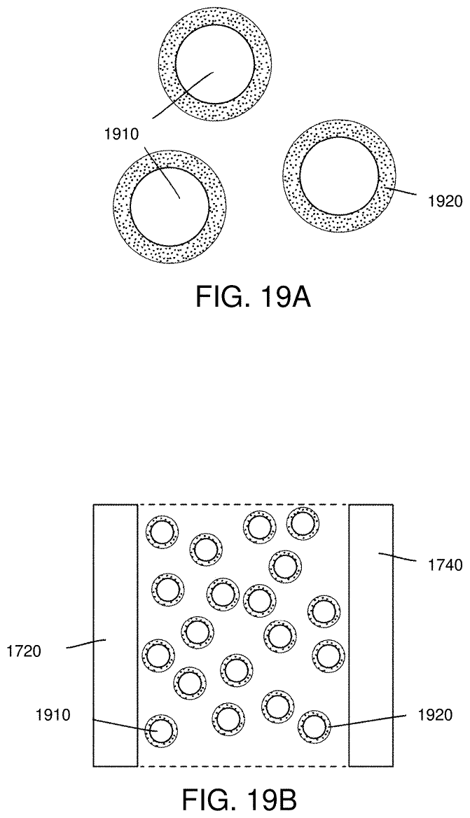

FIG. 21 shows a polyatomic layer including a trap for trap-assisted charge carrier transport, in accordance with some example embodiments. The polyatomic layer (2100) may represent the transport medium (1730) over which a charge carrier may pass between the emitter electrode (1720) and the collector electrode (1740). The polyatomic layer (2100) may comprise a crystalline structure having a polyatomic solid layout analogous to the Ta2O5 system. In one non-limiting implementation, the polyatomic layer (2100) may comprise an amorphous film. In some embodiments, the polyatomic layer (2100) has insulative properties. The crystalline structure of the polyatomic layer (2100) may feature adjoining atoms evenly distributed across a planar area in its natural state. In its natural state, the polyatomic layer (2100) has a balance of bonds between the atoms. Traps may be introduced that disrupt the spacing of the atoms in the polyatomic layer (2100). Traps may be embodied by a defect in the polyatomic layer or as a nanoparticle in the polyatomic layer. The traps may be a natural defect in the polyatomic layer or a metal contaminate introduced into the polyatomic layer (2100). For example, a trap may be a hydrogen atom in place of an oxygen atom in an Al2O₃ atomic structure. The traps increase charge carrier mobility by promoting charge carrier transport across the polyatomic layer (2100). The polyatomic layer (2100) may comprise a polyatomic lattice.

A trap may include an imbalance of bonding between adjacent atoms in the polyatomic layer (2100). This imbalance attracts or repels charge carriers facilitating transport across the transport medium. Examples include a small vacancy trap (2110), a large vacancy trap (2115), a small interstitial trap (2120), a large interstitial trap, a large substitutional trap, and a small substitutional trap (2130). The small vacancy trap (2110) may be characterized by an imbalanced bond missing an electron due to the absence of an atom having a relatively small atomic mass. For example, an imbalanced bond attracts electrons between two tantalum atoms due to a vacancy of an oxygen atom in a Ta2O5 system. The large vacancy trap (2115) may be characterized by an imbalanced bond missing an electron due to the absence of an atom having a relatively large atomic mass. For example, an imbalanced bond attracts electrons between two oxygen atoms due to a vacancy of the larger tantalum atom in a Ta2O5 system. The small interstitial trap (2120) may be characterized by an imbalanced bond with an extra electron bond due to the presence of an extra atom having a relatively small atomic mass. For example, an imbalanced bond repels electrons between tantalum atoms due to an extra smaller oxygen atom in a Ta2O5 system, the oxygen atom having a smaller atomic mass than the tantalum. The large interstitial trap (2125) may be characterized by an imbalanced bond with an extra electron bond due to the presence of an extra atom having a relatively large atomic mass. For example, an imbalanced bond repels electrons between oxygen atoms due to an extra larger tantalum atom in a Ta2O5 system. The large interstitial trap includes a substitutional larger atom having a greater atomic mass than the adjacent atoms may also disrupt the continuity of the balanced bonds in the polyatomic layer (2100). For example, a substitutional larger atom, such as a tantalum atom, may be placed in the polyatomic layer (2100), resulting in stronger bonds between immediately surrounding oxygen atoms. These stronger bonds promote electron mobility by repelling electrons to available electron sites. The small substitutional trap (2130) includes a substitutional smaller atom having a smaller atomic mass than the adjacent atoms may also disrupt the continuity of the balanced bonds in the polyatomic layer (2100). For example, the substitutional smaller atom, such as an oxygen atom, may be placed in the polyatomic layer (2100), resulting in weaker bonds between the immediately surrounding oxygen atoms. These weaker bonds promote electron mobility by repelling electrons across the transport medium (1730). Charge carrier mobility (e.g., electron mobility) may be guided across the transport medium (1730) with proximate vacancies and interstitial pairs. A proximate vacancy and interstitial pair may be considered a Frenkel Pair.

The polyatomic layer (2100) may be a gas, vapor, solid, solution, a solution with nanoparticles, or a solid with nanoparticles. The polyatomic layer (2100) may have insulating or semiconductor properties, including low electrical conductivity and/or low thermal conductivity. The polyatomic layer (2100) may comprise any material for the transport medium (1730). The trap may comprise the nanoparticles embedded in a solid material or nanoparticles situated in a fluid. The traps may have strong or excessive electron bonds in comparison to the electron bonds in the polyatomic layer (2100). The traps may have weak or vacant electron bonds in comparison to the electron bonds in the polyatomic layer (2100). The traps may include a discrete site of a bonding imperfection in the polyatomic layer (2100). The traps may enhance charge carrier transport across the transport medium (1730). In some embodiments, traps may be formed at defects within the insulating or semiconductor crystalline structure of the polyatomic layer (2100).

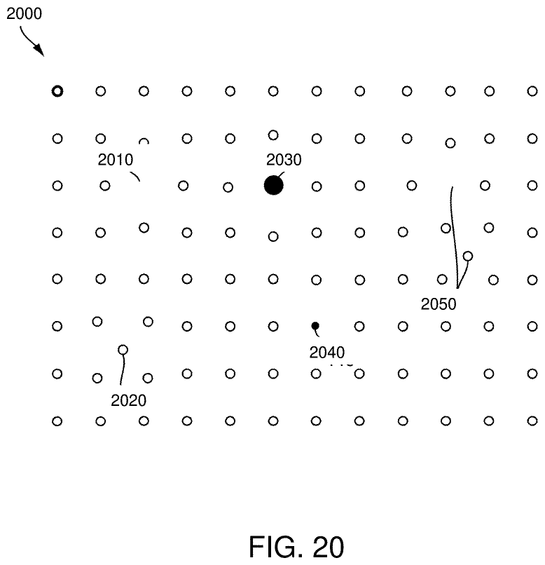

FIG. 22 shows a bandgap diagram depicting applied charge carrier quantum tunneling techniques and Poole-Frenkel Emission in accordance with some example embodiments. The term “quantum tunneling” is not limited to the definition of a charge carrier passing from one end of the transport medium (1730) to the opposite end of the transport medium (1730). The term “quantum tunneling” may also include direct tunneling, trap-assisted tunneling, phonon-assisted tunneling, Fowler-Nordheim tunneling, and leakage tunneling. For example, quantum tunneling may occur between charge carrier traps in the transport medium (1730) without traversing the entire transport medium (1730) in a single movement. Quantum tunneling (2210) may characterize the charge carrier transportation across the nanoparticle solution-based transport medium and the solid-state transport medium (1730). Quantum tunneling (2210) may optimize charge carrier migration between the emitter electrode (1720) and the collector electrode (1740). Quantum tunneling (2210) may optimize charge carrier mobility from electrodes having a lower work function to electrodes having a higher work function.

The Quantum tunneling effect may be controlled by the thickness of the transport medium (1730). Quantum tunneling is very sensitive to the distance that a charge carrier (e.g., an electron) travels between the emitter electrode (1720) and the collector electrode (1740). The transport medium (1730) may be resized to increase the quantum tunneling effect. A thinner transport medium (1730) may be preferable in its capacity to promote higher charge carrier migration according to quantum tunneling effects. A thicker transport medium (1730) generally reduces the quantum tunneling effect.

As shown in FIG. 22, a transport medium (1730) has a high energy barrier compared to the emitter electrode. Even though the energy barrier is higher than the emitter electrode, a finite probability exists that a charge carrier may cross through the transport medium (1730) based on the wavelike behavior of the charge carrier on a quantum scale. If the transport medium (1730) is sufficiently thin, the charge carrier may tunnel through the energy barrier of the transport medium (1730) from a lower work function to a higher work function. In some non-limiting implementations, the charge carriers may flow through the transport medium (1730) from the higher work function to the lower work function. As shown, the emitter electrode (1720) has a lower work function than the collector electrode (1740) has a higher work function.

The nanoparticle solution-based transport medium and the solid-state transport medium may be sufficiently thin to support quantum tunneling. The emitter electrode (1720) and the collector electrode (1740) may be configured to have a sufficient work function differential to facilitate electron transportation across the transport medium (1730). The nanoparticle solution-based transport medium and the solid-state transport medium may be adjusted to increase the quantum tunneling effect.

As shown in FIG. 22, trap-assisted tunneling (2220) may occur between two metal electrodes. Trap-assisted tunneling (2220) may be depicted with a bandgap diagram in accordance with some example embodiments. Trap-assisted tunneling (2220) may characterize the charge carrier transportation across the transport medium. Trap-assisted tunneling (2220) may optimize electron migration between the emitter electrode (1720) and the collector electrode (1740) by splitting the energy barrier into two or more parts. This enables a consecutive tunnel through thinner energy barriers and increases the probability that a charge carrier will pass through the transport medium (1730). Trap-assisted tunneling (2220) enables thicker transport mediums in comparison to transport mediums utilizing quantum tunneling (2210).

The nanoparticles may control the probability and frequency of charge carriers passing through the transport medium (1730) using the trap-assisted tunneling effect. Generally, additional nanoparticles in the transport medium (1730) increase the probability that a charge carrier will pass through the transport medium (1730) via trap-assisted tunneling (2220). The nanoparticles may be resized to increase the probability and frequency of charge carriers passing through the transport medium (1730) using the trap-assisted tunneling effect. Alternatively, and/or additionally, traps may be introduced into the atomic layer to split the energy barrier of the transport medium (1730) into two or more parts. Generally, more traps in the transport medium (1730) increase the probability that a charge carrier will pass through the transport medium (1730) via trap-assisted tunneling (2220).

As shown in FIG. 22, Poole-Frenkel emission (2230) may occur between two metal electrodes. Poole-Frenkel emission (2230) may be depicted with a bandgap diagram in accordance with some example embodiments. Poole-Frenkel emission (2230) may characterize the charge carrier transportation across the transport medium (1730). Poole-Frenkel emission (2230) may optimize charge carrier migration between the emitter electrode (1720) and the collector electrode (1740). The nanoparticles may control the probability and frequency of charge carriers passing through the transport medium (1730) using the Poole-Frenkel emission effect. Generally, additional nanoparticles in the transport medium (1730) increase the probability that the charge carrier will pass through the transport medium (1730) via Poole-Frenkel emission (2230). The nanoparticles may be resized to increase the probability and frequency of charge carriers passing through the transport medium (1730) using the Poole-Frenkel effect. Alternatively, and/or additionally, traps may be introduced into the atomic layer to split the energy barrier into two or more parts. Generally, more traps in the transport medium (1730) increase the probability that a charge carrier will pass through the transport medium (1730) via Poole-Frenkel emission (2230). In at least one non-limiting implementation, the traps in the transport medium (1730) form a discontinuous energy band or defect energy band.

The term “work function” is not limited to the definition of the minimum quantity of energy required to remove a charge carrier from a surface (e.g., an electrode) to a vacuum. The term “work function” may include the ability to manipulate the potential energy landscape for moving a charge carrier from a surface (e.g., an electrode) to another surface. The potential energy landscape may be characterized by the work functions of the surfaces and the various features of the energy barrier, such as an energy barrier height relative to the fermi level, an energy barrier height relative to vacuum, an energy barrier slope, a density of traps within the energy barrier, a depth of the traps within the energy barrier, and an intermediate stage adjacent to the energy barrier. Manipulating the characteristics of the energy barrier enables various non-equilibrium states for moving a charge carrier to another surface.

The energy barrier may be modified by adjusting the energy barrier height relative to the fermi level. This height may be adjusted by combining a first material and a second material that determine a maximum height of the energy barrier relative to the fermi level. For example, the first material may determine the initial barrier height and the second material may raise or lower the energy barrier height, determining the maximum height. In one non-limiting example, the first material and second material are oxides where the second material lowers the energy barrier height relative to the fermi level as initially determined by the first material.

The energy barrier may be modified by adjusting the energy barrier height relative to the vacuum level. This energy barrier height relative to the vacuum level may be adjusted by combining a first material and a second material that determine a height of the energy barrier relative to the vacuum level. For example, the first material may determine the initial barrier height relative to the vacuum level and the second material may raise or lower the energy barrier height relative to the vacuum level. In one non-limiting example, the first and second materials are oxides where the second material lowers the energy barrier height initially determined by the first material.

The energy barrier may be modified by adjusting the energy barrier slope. The energy barrier slope may be adjusted by combining a first material and a second material that comprise the energy barrier. For example, the first material may have a first barrier slope and the second material may have a second barrier slope. Combining the first material and the second material causes the first barrier slope to decrease the energy required to move the charge carrier through the transport medium (1730) at a higher rate than the first barrier slope standing alone. In one non-limiting example, the first and second materials are oxides where the second material has a steeper slope relative to the first material. Energy barrier slope may be the biggest determining factor of the non-equilibrium state.

The energy barrier may be modified by adjusting a density of traps within the energy barrier. The density of traps may vary depending on the nanoparticles in the fluid and/or solid. The density of traps may vary depending on the current across the transport medium (1730). The density of traps may vary depending on the number of defects or impurities or deposition method of the transport material. In a non-limiting example, gold nanoparticles may be immersed in nanoparticle solution (1810) comprising tetradecane. The density of traps within the energy barrier may be adjusted based on the number and the diameter of the nanoparticles.

The energy barrier may be modified by adjusting a depth of traps within the energy barrier. The depth of the traps may vary depending on the conductivity, resistance, and density of nanoparticles in the fluid and/or solid. The depth of the traps may vary depending on whether the nanoparticle is mobile within the nanoparticle fluid. The depth of the traps may depend on the atomic nature of the defect or impurity or the nature of atomic bonding with surrounding atoms in the transport material. In a non-limiting example, gold nanoparticles may be immersed in nanoparticle solution (1810) comprising tetradecane. The depth of the traps within the energy barrier may be adjusted based on the density and the diameter of the nanoparticles.

The energy barrier may be modified by an intermediate stage adjacent to the energy barrier. The intermediate stage adjacent to the energy barrier may be adjusted by combining a first material and a second material that comprise the energy barrier. For example, the first material may determine a fermi level and the second material may determine the height and width of intermediate stage. In one non-limiting example, the first and second materials are oxides where the second material creates the intermediate stage. Various intermediate states may exist between a fermi level and the energy required to move the charge carrier to vacuum. There may be other defect states at the intermediate stage, which enable a subset of charge carriers to escape to the emitter or the collector at a different energy level. In one non-limiting example, the defect states may be included in a graduated density to vary the slope of the energy barrier.

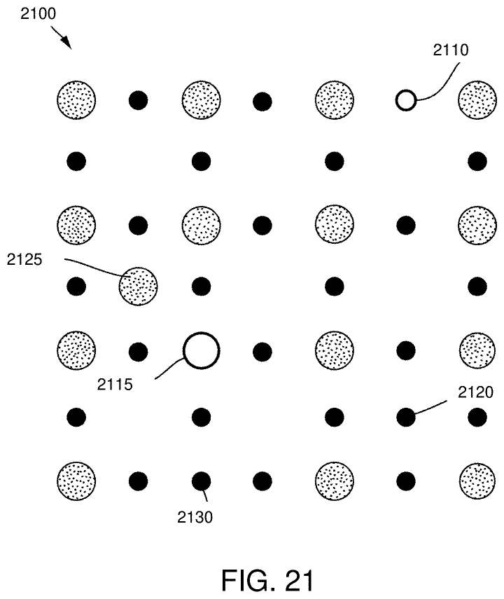

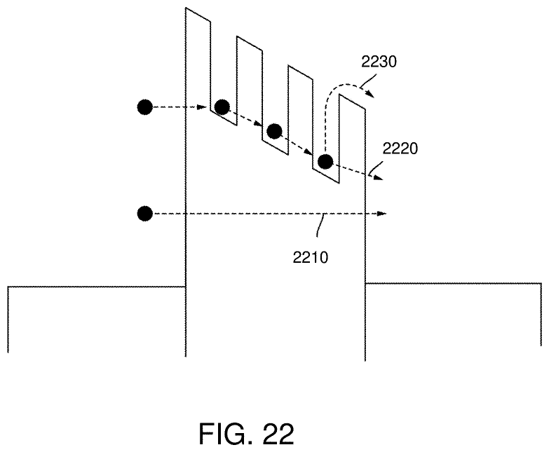

FIG. 23 shows another bandgap diagram depicting applied charge carrier tunneling techniques and Poole-Frenkel Emission in accordance with some example embodiments. In some embodiments, quantum tunneling (2210) may optimize charge carrier mobility from surfaces having a higher work function to surfaces having a lower work function. The transport medium (1730) may be resized to increase the quantum tunneling effect. A thinner transport medium (1730) may be preferable in its capacity to promote higher electron migration according to quantum tunneling effects. A thicker transport medium (1730) generally reduces the quantum tunneling effect. The nanoparticle solution-based transport medium and the solid-state transport medium may be sufficiently thin to support quantum tunneling. The emitter electrode (1720) and the collector electrode (1740) may be configured to have a sufficient work function differential to facilitate charge carrier transportation across the transport medium (1730). The nanoparticle solution-based transport medium and the solid-state transport medium may be adjusted to increase the quantum tunneling effect. Various combinations of materials and/or operational conditions may determine whether the charge carriers travel from the high work function surface (1728) to the low work function surface (1726).

In a similar manner, trap-assisted tunneling (2220) may optimize charge carrier mobility from surfaces having a higher work function to surfaces having a lower work function. Trap-assisted tunneling (2220) may optimize electron migration by splitting the energy barrier of the transport medium (1730) into two or more parts. Splitting the energy barrier enables a consecutive tunnel through thinner energy barriers and increases the probability that charge carriers will pass through the transport medium (1730). In some embodiments, the charge carrier may travel to a higher work function energy barrier to a lower work function energy barrier. Trap-assisted tunneling (2220) enables thicker transport mediums in comparison to transport mediums utilizing quantum tunneling (2210).

The nanoparticles may control the probability and frequency of charge carriers passing through the transport medium (1730) using the trap-assisted tunneling effect. Generally, additional nanoparticles in the transport medium (1730) increase the probability that a charge carrier will pass through the transport medium (1730) via trap-assisted tunneling (2220). The nanoparticles may be resized to increase the probability and frequency of charge carriers passing through the transport medium (1730) using the trap-assisted tunneling effect. Alternatively, and/or additionally, traps may be introduced into the atomic layer to split the energy barrier of the transport medium (1730) into two or more parts. Generally, more traps in the transport medium (1730) increase the probability that a charge carrier will pass through the transport medium (1730) via trap-assisted tunneling (2220). Various combinations of materials and/or operational conditions may determine whether the charge carriers travel from the high work function surface (1728) to the low work function surface (1726).

In a similar manner, Poole-Frenkel emission (2230) may optimize charge carrier mobility from surfaces having a higher work function to surfaces having a lower work function. The nanoparticles may control the probability and frequency of charge carriers passing through the transport medium (1730) using the Poole-Frenkel emission effect. Generally, additional nanoparticles in the transport medium (1730) increase the probability that a charge carrier will pass through the transport medium (1730) via Poole-Frenkel emission (2230). The nanoparticles may be resized to increase the probability and frequency of charge carriers passing through the transport medium (1730) using the Poole-Frenkel effect. Alternatively, and/or additionally, traps may be introduced into the atomic layer to split the energy barrier into two or more parts. Generally, more traps in the transport medium (1730) increase the probability that a charge carrier will pass through the transport medium (1730) via Poole-Frenkel emission (2230). Various combinations of materials and/or operational conditions may determine whether the charge carriers travel from the high work function surface (1728) to the low work function surface (1726).

FIGS. 22A-22D show various views of standoff pillars resulting from an etch, in accordance with some example embodiments. The transport medium (1730) may be incapable of supporting the emitter electrode (1720) and/or the collector electrode (1740). For example, the transport medium (1730) may be unstable if the transport medium (1730) primarily comprises a nanoparticle solution (1810) or other non-solid material. The transport medium (1730) comprising the nanoparticle solution (1810) may integrate the standoff pillars (2410) for stability of the individual cell and the stacked architecture.

The standoff pillars (2410) may be interposed between the emitter electrode (1720) and the collector electrode (1740) in the transport medium (1730). The standoff pillars (2410) may have low thermal and electrical conductivity. The standoff pillars (2410) may have a larger footprint near the emitter electrode (1720) than the collector electrode (1740). Alternatively, the standoff pillars (2410) may have a larger footprint near the collector electrode (1740) for modifying the work function. The standoff pillars (2410) may connect at or near the emitter electrode (1720). The top and bottom of the standoff pillars (2410) may be substantially planar at both the points of contact with the emitter electrode (1720) and the collector electrode (1740).

The standoff pillars (2410) may be created using an etch process. gas or vapor may etch material in the transport medium (1730). The gas or vapor may have high selectively against etching the emitter electrode (1720), the collector electrode (1740), or the substrate. In other embodiments, the standoff pillars (2410) may be created using deposition techniques, such as PVD, CVD, spin-on coating, self-assembly, etching, lithography, and/or a similar manufacturing process.

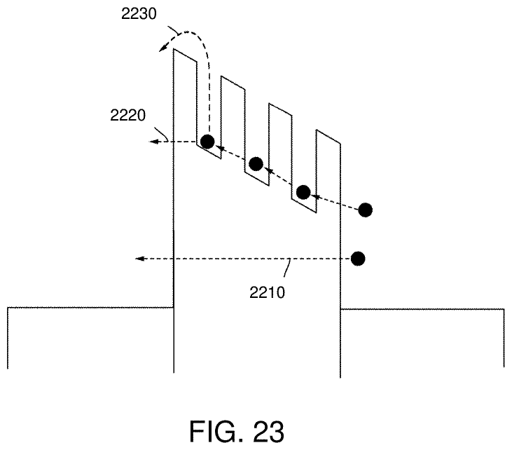

FIGS. 25A-25D show an exploded view of standoff columns resulting from an etch, in accordance with some example embodiments. The transport medium (1730) may be incapable of supporting the emitter electrode (1720) and/or the collector electrode (1740). For example, the transport medium (1730) may be unstable if the transport medium (1730) primarily comprises a nanoparticle solution (1810). The transport medium (1730) comprising the nanoparticle solution (1810) may integrate standoff columns for stability of the individual cell and the stacked architecture.

The standoff columns (2520) may be interposed between the emitter electrode (1720) and the collector electrode (1740) in the transport medium (1730). The standoff columns (2520) may have low thermal and electrical conductivity. The standoff columns (2520) may have a larger footprint near the emitter electrode (1720) than the collector electrode (1740). Alternatively, the standoff columns (2520) may have a larger footprint near the collector electrode (1740) for modifying the work function. The standoff columns (2520) may connect at or near the emitter electrode (1720). The top and bottom of the standoff columns (2520) may be substantially planar at both the points of contact with the emitter electrode (1720) and the collector electrode (1740).

The standoff columns (2520) may be created using an etch process. A gas or vapor may etch material in the transport medium (1730). The gas or vapor may have high selectively against etching the emitter electrode (1720), the collector electrode (1740), or the substrate. In other embodiments, the standoff columns (2520) may be created using deposition techniques, such as PVD, CVD, spin-on coating, self-assembly, etching, lithography, and/or a similar manufacturing process.

Non-solid transport mediums may require standoff pillars to maintain spacing between the emitter electrode (1720) and the collector electrode (1740). The standoff pillars (2410) and standoff columns (2520) may be scaled to maximize electron flow. For example, the standoff pillars (2410) and standoff columns (2520) are designed to provide maximum support with the smallest available footprint. The standoff pillars (2410) and standoff columns (2520) may be thermally insulated and electrically insulated to maximize electron flow. The standoff pillars (2410) and standoff columns (2520) may be free-standing nanolaminate structures.

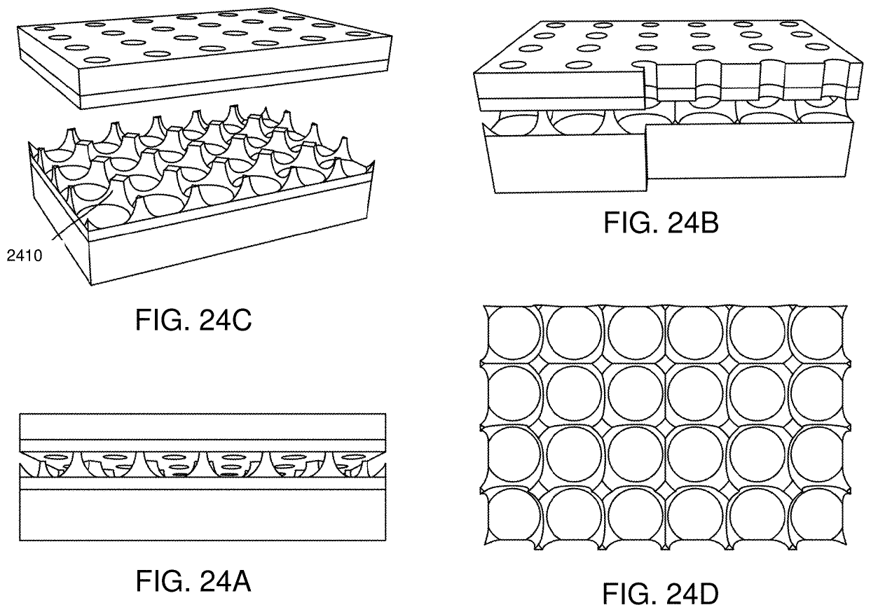

FIG. 26 shows a block diagram of the energy conversion device coupled to an application device. The energy conversion device (1705) may be coupled to an application device (2620) or any of a wide variety of devices or systems for providing power to such devices and systems. The energy conversion device (1705) is configured to directly or indirectly provide power to the application device (2620). The energy conversion device (1705) can be externally coupled to the application device (2620), or it may be incorporated as part of the application device (2620). The application device (2620) may include a battery charging system, an electronic device, a climate control system, a portable power system, a stationary power system, a backup power device, and/or an environmental sensor, as described in some non-limiting examples below.

In an implementation, the energy conversion device (1705) may be configured to generate power in a battery charging system. In some embodiments, the battery charging system may include a gridless battery charging system or a wearable battery charging system. The battery charging system may be configured for powering an electrically powered vehicle, an electrically powered boat, an electrically powered aircraft, and/or the like. The battery charging system may be configured to support a power source (e.g., a battery) for increasing electric energy storage or extending a range of a vehicle.

In another implementation, the energy conversion device (1705) may be configured to generate power in an electronic device. In some embodiments, the electronic device may include a computer, a processor, a memory, a sensor, a wireless range extender, a cellular device, a mobile device, a watch, a tablet, a wearable electronic device, a medical device (e.g., a pacemaker, a hearing aid, an implantable sensor), an IoT device, and/or the like. Wearable devices may include an accelerometer, an accelerometer in a helmet, an accelerometer attached to a head, an accelerometer for measuring athletic performance, an oxygen meter, a temperature sensor, a sweat salinity sensor, and an impact sensor. The energy conversion device may be configured to generate power in an electronic system. In some embodiments, the electronic system may include a communication network, a cellular communication system, and/or the like.

In another implementation, the energy conversion device (1705) may be configured to generate power in a climate control system. In some embodiments, the climate control system may include a satellite cooling system or an electronics cooling system. The electronics cooling system may be configured for powering an amplifier, a radar system, a laser system, a processor, a memory, a computer component, a battery cooling system, and/or the like. The climate control system may be configured to power a data center for reducing power consumption and waste heat. The climate control system may be configured to support a power source (e.g., a battery) for increasing electric energy storage or extending an operating time of an electronic component.

In another implementation, the energy conversion device (1705) may be configured to generate power in a portable power system. In some embodiments, the portable power system may include a high-reliability all-weather power system, a high-reliability, noise-free power system, a self-powered lighting system, a heat pump, a heat pump for satellites or space vehicles, and/or the like.

In another implementation, the energy conversion device (1705) may be configured to generate power in a stationary power system. In some embodiments, the stationary power system may include a generator, a heat pump, an air-conditioning unit, a climate control unit, a high-reliability, low-maintenance stationary power system, and/or the like. The energy conversion device (1705) may be configured to support an energy harvesting apparatus. The energy conversion device (1705) may be configured to support a solar cell, a solar panel, a wind turbine, a windmill, a geothermal heat pump, and/or the like.

In another implementation, the energy conversion device (1705) may be configured to generate power for a backup power device. In some embodiments, the backup power device may include a communication system failsafe device, a smoke detector failsafe device, a carbon monoxide detector failsafe device, and a toxic gas sensor failsafe device configured to detect hydrofluoric acid, boron trifluoride, phosphoryl chloride, methane, and/or the like.

In another implementation, the energy conversion device (1705) may be configured to generate power for an environmental sensor. In some embodiments, the environmental sensor may be a sensor buoy device, a microelectromechanical system (MEMS) device, a remote device, and/or the like.

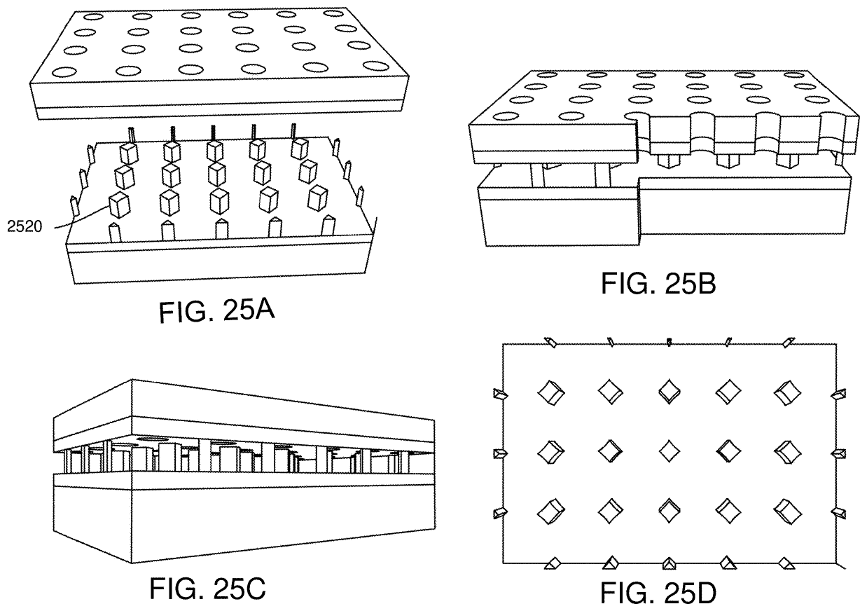

FIG. 27 shows a block diagram of an energy conversion system for an application. An energy conversion system (2700) may include an energy conversion device (1705), a distributor (2710), an environment (2720), a power converter (2730), and an application device (2620). The energy conversion device (1705) may interface with a distributor (2710) for equal dispersion of energy across the energy conversion device (1705). The distributor (2710) equally disperses the energy (e.g., heat) harvested from the environment (2720) to the energy conversion device (1705). The energy conversion device (1705) may be coupled to a power converter (2730). The power converter (2730) may be coupled to an application device (2620) or any wide variety of devices or systems for providing power to such devices and systems. The energy conversion system (2700) is configured to directly or indirectly provide power to the application device (2620). The energy conversion system (2700) can be externally coupled to the application device (2620), or it may be incorporated as part of the application device (2620). Some non-limiting examples are described below.

The distributor (2710) may be a thermal packaging that couples to the energy conversion device (1705). The distributor (2710) may enable the energy conversion device (1705) to evenly absorb and/or conduct energy from the environment (2720). For example, the distributor (2710) may be a heat sink to allow the leads of the energy conversion device (1705) to absorb thermal energy evenly. The distributor (2710) may regulate the energy intake to avoid damaging the energy conversion device (1705).

The power converter (2730) may reduce noise and produce a steady stream of power received from the energy conversion device (1705). The power converter (2730) may be a combination of inductors and capacitors arranged to reduce noisy voltage of the energy conversion device (1705). Additionally, and/or alternatively, the power converter (2730) may boost or reduce the voltage received from the energy conversion device (1705).

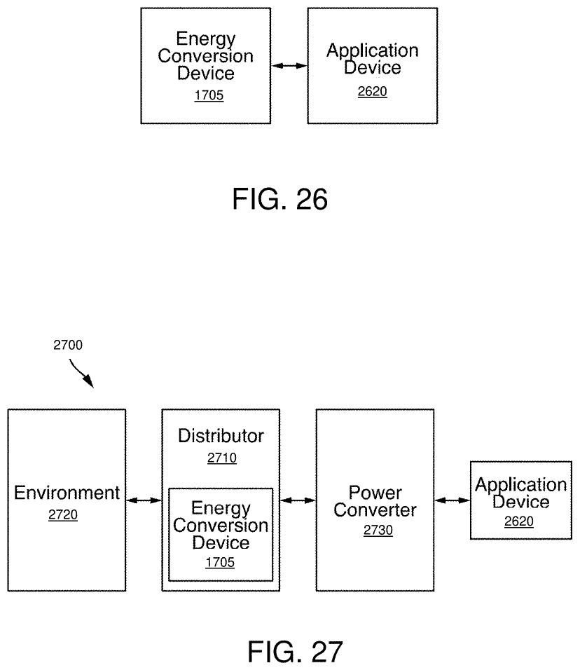

FIG. 28 shows another block diagram of an energy conversion system including an output controller coupled to an application device. An energy conversion control system (2800) may include an energy conversion device (1705), a distributor (2710), a power converter (2730), an output controller (2810), a fast power storage (2820), a slow power storage (2830), and an application device (2620). The energy conversion control system (2800) may interface with a distributor (2710) for equal dispersion of energy across the energy conversion device (1705). The energy conversion device (1705) may be coupled to the power converter (2730). The power converter (2730) may be coupled to the output controller (2810), the fast power storage (2820), and the slow power storage (2830). The fast power storage (2820) and the slow power storage (2830) may couple to the output controller (2810). The output controller (2810) may be coupled to an application device (2620) or any wide variety of devices or systems for providing power to such devices and systems. The output controller (2810) may transfer power from the energy conversion device (1705) to the application device (2620). The energy conversion control system (2800) is configured to directly or indirectly provide power to the application device (2620). The energy conversion control system (2800) can be externally coupled to the application device (2620), or it may be incorporated as part of the application device (2620). Some non-limiting examples are described below.

The output controller (2810) may communicate with the application device (2620) to determine the power to deliver to the application device from the power converter (2730), the fast power storage (2820), and/or the slow power storage (2830). For example, the application device (2620) may send a control signal to the output controller (2810), instructing the output controller (2810) to increase the delivered power when a threshold is reached. Additionally, the control signal may respond to or incorporate performance information from the application device (2620). The output controller may include closed-loop PID logic to provide a more responsive control system. The output controller (2810) may switch or balance the needed power load across the energy conversion device (1705) and any storage systems in order to provide the required electrical power output to the application device (2620).

The fast power storage (2820) may enable the energy conversion device (1705) to meet duty cycle requirements or peak power requirements without increasing the size or capacity of the energy conversion device (1705). For example, a capacitor, ultracapacitor, or a supercapacitor may be charged quickly to match the demand of the application device (2620) or to absorb a burst of energy from the energy conversion device (1705). Slow power storage (2830) may enable the energy conversion device (1705) to store power over extended periods of time to respond to increased demand in power at a later time. For example, a battery can maintain its power level for an extended period of time for later use by the application device (2620).

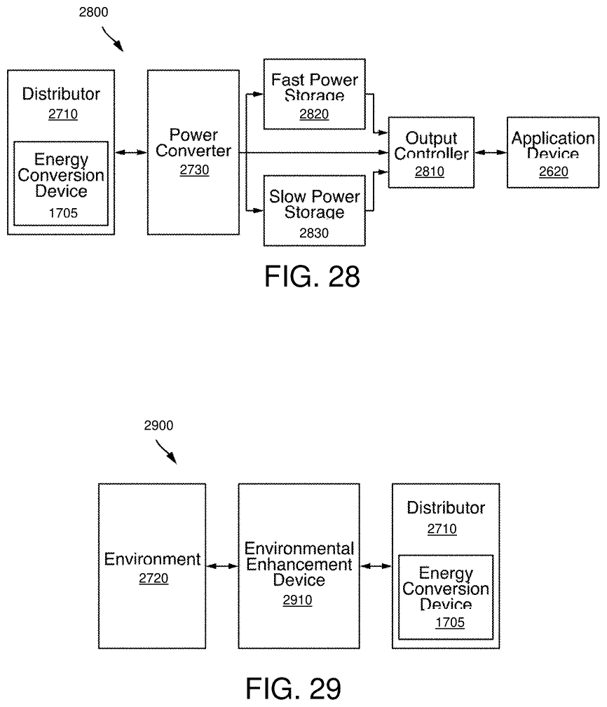

FIG. 29 shows another block diagram of an energy conversion system including an environmental enhancement. An enhanced energy conversion system (2900) may include an energy conversion device (1705), a distributor (2710), an environment (2720), and an environmental enhancement device (2910). The energy conversion device (1705) may interface with a distributor (2710) for equal dispersion of energy across the energy conversion device (1705). The energy conversion device (1705) may be coupled to the environmental enhancement device (2910). The enhanced energy conversion system (2900) may be configured to directly or indirectly supply energy to the energy conversion device (1705). The enhanced energy conversion system (2900) can be externally coupled to the distributor (2710), or it may be incorporated as part of the distributor (2710). Some non-limiting examples are described below.

The environmental enhancement device (2910) may maximize the absorption of energy from the environment. The environmental enhancement device (2910) may radiate energy onto the distributor (2710). Additionally, and/or alternatively, the environmental enhancement device (2910) may apply convection techniques to increase the energy received by the distributor (2710). Additionally, and/or alternatively, the environmental enhancement device (2910) may apply conduction techniques to increase the energy received by the distributor (2710). The environmental enhancement device (2910) may be externally coupled to the distributor (2710), or it may be incorporated as part of the distributor (2710).

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The implementations set forth in the foregoing description do not represent all implementations consistent with the subject matter described herein. Instead, they are merely some examples consistent with aspects related to the described subject matter. Although a few variations have been described in detail herein, other modifications or additions are possible. In particular, further features and/or variations can be provided in addition to those set forth herein. For example, the implementations described above can be directed to various combinations and sub-combinations of the disclosed features and/or combinations and sub-combinations of one or more features further to those disclosed herein. In addition, the logic flows depicted in the accompanying figures and/or described herein do not necessarily require the particular order shown, or sequential order, to achieve desirable results. The scope of the following claims may include other implementations or embodiments. An electron is considered to be a charge carrier. The term “electron” may be interchangeable with charge carrier.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

While the foregoing is directed to implementations of the present disclosure, other and further implementations of the disclosure may be devised without departing from the basic scope thereof, and the scope thereof is determined by the claims that follow.

What is claimed is:

1. An apparatus, comprising:
a transport medium comprising a nanoparticle suspended in a dielectric, the transport medium having a first side and a second side, the first side opposing the second side, the nanoparticle comprising a conductive metal, the conductive metal at least partially covered by a monolayer film, the monolayer film being less conductive than the conductive metal;
a first surface disposed at the first side of the transport medium, the first surface having a first work function; and
a second surface disposed at the second side of the transport medium, the second surface having a second work function,
wherein the first work function is lower than the second work function, and
wherein the apparatus is configured to power an application device coupled to the apparatus.

2. The apparatus of claim 1, wherein a nanoparticle work function is lower than the second work function.

3. The apparatus of claim 1, wherein the dielectric is a solution comprising at least one of silicone oil, purified water, hexane, toluene, and tetradecane.

4. The apparatus of claim 1, wherein the monolayer film has a thickness less than ten nanometers, and wherein the conductive metal of the nanoparticle comprises at least one of gold, silver, platinum, titanium, platinum, lanthanum hexaboride, and copper.

5. The apparatus of claim 1, wherein the nanoparticle further comprises a core-shell nanoparticle, the core-shell nanoparticle including a conductive core and an insulative film.

6. The apparatus of claim 1, wherein the first surface comprises a surface feature including at least one of a spike, a sphere, a pin, and a pillar.

7. The apparatus of claim 1, wherein the first surface comprises at least one of Cs2O, CsF, CH3OH, CsCO3, chlorine compounds, fluorine compounds, cesium compounds, non-stoichiometric cesium oxides, and cesium fluorides.

8. The apparatus of claim 1, wherein the first surface comprises a semi-conductive material, the semi-conductive material being doped with at least one of aluminum, antimony, bismuth, gold, phosphorous and boron.

9. The apparatus of claim 1, wherein the first surface has covalent bonding in-plane and Van der Waals bonding out of plane, and wherein the first surface comprises at least one of WSe2, MoS2, MoTe2, and h-BN.

10. The apparatus of claim 1, wherein a first end and a second end of the transport medium include a sealant and a standoff, and wherein the first surface has a surface thickness less than one nanometer, the first surface including at least one of graphene, Si2BN, and borophene.

11. An apparatus, comprising:
a first electrode having a first surface, the first surface having a first work function;
a second electrode having a second surface, the second surface having a second work function; and
a transport medium interposed between the first surface and the second surface, the transport medium comprising traps suspended in a dielectric,
wherein the first work function is lower than the second work function, and
wherein the apparatus is configured to power an application device coupled to the apparatus.

12. The apparatus of claim 11, wherein the dielectric comprises a lattice of Ta2O5 and a tantalum dopant and the traps include an opening in the lattice of Ta2O5 where no atom is bonded to the tantalum dopant.

13. The apparatus of claim 11, wherein the first electrode and the second electrode have a surface treatment comprising at least one of Cs2O, CsF, CH3OH, CsCO3, chlorine compounds, fluorine compounds, cesium compounds, non-stoichiometric cesium oxides, and cesium fluorides.

14. The apparatus of claim 11, wherein the dielectric is a polycrystalline layer having a crystalline structure, the traps are nanoparticles including a conductive metal, and wherein the first electrode comprises a semi-conductive material and the second electrode comprises at least one of Ti, Ni, Cu, Pd, Ag, Hf, ITO, W, Jr, Pt, and Au.

15. An apparatus, comprising:
a first electrode having a first surface and a second surface, the first surface and the second surface being associated with a first work function;
a second electrode facing the first surface, the second electrode associated with a second work function;
a third electrode facing the second surface, the third electrode associated with the second work function;
a first transport medium interposed between the first electrode and the second electrode; and
a second transport medium interposed between the first electrode and the third electrode,
wherein the second electrode and the third electrode are electrically coupled and the first work function is lower than the second work function, and
wherein the apparatus is configured to power an application device coupled to the apparatus.

16. The apparatus of claim 15, wherein the first electrode and the second electrode are on opposing sides of the first transport medium, and wherein the second electrode and the third electrode are on opposing sides of the second transport medium.

17. The apparatus of claim 15, wherein the first surface contacts the first transport medium and the second surface contacts the second transport medium.

18. The apparatus of claim 15, further comprising:
a first lead, the first lead oriented in a first direction non-parallel to the first surface and the second surface, the first lead electrically connected to the second electrode and the third electrode; and
a second lead, the second lead oriented in a second direction non-perpendicular to the first lead, the second lead electrically coupled to the first electrode.

19. The apparatus of claim 18, wherein the first direction is the same as the second direction, and wherein the first lead extends at least a distance between the second electrode and the third electrode.

20. The apparatus of claim 18, wherein the second lead faces an exposed region of the first electrode, and wherein the first lead is on an opposing side of the exposed region of the first electrode.
